(19) United States
(12) Patent Application Publication
(10) Pub. No.: US 2026/0130297 A1
(43) Pub. Date: May 7, 2026

(54) ELECTRONIC DEVICE

(71) Applicant: ROHM CO., LTD., Kyoto-shi (JP)

(72) Inventor: Ryohei UMENO, Kyoto-shi (JP)

(21) Appl. No.: 19/434,178

(22) Filed: Dec. 29, 2025

Related U.S. Application Data
(63) Continuation of application No. PCT/JP2024/021456, filed on Jun. 13, 2024.

(30) Foreign Application Priority Data
Jul. 4, 2023 (JP) 2023-110016

(51) Int. Cl. H10W 90/00; H10W 70/40; H10W 90/10; H10W 74/10

(52) U.S. Cl. CPC H10W 90/811; H10W 70/421; H10W 90/10; H10W 74/114; H10W 90/753; H10W 90/756

(57) ABSTRACT

An electronic device includes an electronic component, a sealing resin, and a lead with an inner portion and an outer portion. The inner portion includes a die pad portion on which the electronic component is mounted, and a connecting portion that connects the outer portion and the die pad portion. The outer portion is disposed on a side of a first direction relative to the die pad portion. The connecting portion is connected to a side surface of the die pad portion. In a second direction, the center of the outer portion is disposed on a side of the second direction relative to the center of the die pad portion. The side surface includes a connecting section connected to the connecting portion and a pair of lateral sections disposed on both sides of the connecting section in the second direction.

### TECHNICAL FIELD

### The present disclosure relates to electronic devices

### BACKGROUND ART

Conventionally, semiconductor devices manufactured using lead frames are known as one type of electronic device. An example of such a semiconductor device is disclosed in JP-A-2022-55599. The semiconductor device disclosed in JP-A-2022-55599 is configured to be surface-mounted on a wiring board of an inverter device and comprises a first semiconductor element, a conductive support member, and a sealing resin. The conductive support member is formed from a single lead frame. The conductive support member includes a first die pad and input terminals. The first semiconductor element is mounted on the first die pad. The input terminals include some terminals connected to the first die pad.

### BRIEF DESCRIPTION OF THE DRAWINGS

FIG. 1 is a plan view showing an electronic device of a first embodiment

FIG. 2 shows the plan view of FIG. 1 with the sealing resin depicted with imaginary lines.

FIG. 3 is an enlarged plan view of a portion of FIG. 2.

FIG. 4 is an enlarged plan view of a portion of FIG. 2.

FIG. 5 is a front view showing the electronic device of the first embodiment.

FIG. 6 is a rear view of the electronic device of the first embodiment.

FIG. 7 is a left side view of the electronic device of the first embodiment.

FIG. 8 is a right side view of the electronic device of the first embodiment.

FIG. 9 is a cross-sectional view along line IX-IX in FIG. 2.

FIG. 10 is a cross-sectional view along line X-X in FIG. 2.

FIG. 11 is a perspective view showing the first die pad portion and the first electronic component in the electronic device of the first embodiment.

FIG. 12 is a perspective view showing the second die pad portion and the second electronic component in the electronic device of the first embodiment.

FIG. 13 shows the circuit configuration of the first electronic component and the second electronic component in the electronic device of the first embodiment.

FIG. 14 is a plan view showing a process for manufacturing the electronic device of the first embodiment.

FIG. 15 is a plan view showing an electronic device of a first variation of the first embodiment, wherein the sealing resin is shown by imaginary lines.

FIG. 16 is a front view showing the electronic device of the first variation of the first embodiment.

FIG. 17 is a rear view of the electronic device of the first variation of the first embodiment.

FIG. 18 is a plan view showing an electronic device of a second variation of the first embodiment, with the sealing resin indicated by imaginary lines.

FIG. 19 is a plan view showing an electronic device of a third variation of the first embodiment, with the sealing resin indicated by imaginary lines.

FIG. 20 is a plan view showing an electronic device of a fourth variation of the first embodiment, wherein the sealing resin is shown by imaginary lines.

FIG. 21 shows the circuit configuration of the first electronic component and the second electronic component in the electronic device of the fourth variation of the first embodiment.

FIG. 22 is a plan view showing an electronic device based on another configuration of the fourth variation, wherein the sealing resin is shown by imaginary lines.

FIG. 23 is a plan view showing main parts of an electronic device of a second embodiment.

FIG. 24 is a plan view showing main parts of the electronic device of the second embodiment.

### DETAILED DESCRIPTION OF EMBODIMENTS

Preferred embodiments of electronic devices of the present disclosure will be described below with reference to the drawings. Hereinafter, identical or similar components will be designated by the same reference numerals to avoid redundant descriptions. The terms “first,” “second,” “third,” etc., in the present disclosure are used merely as labels and do not necessarily imply any particular order of the objects they refer to.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

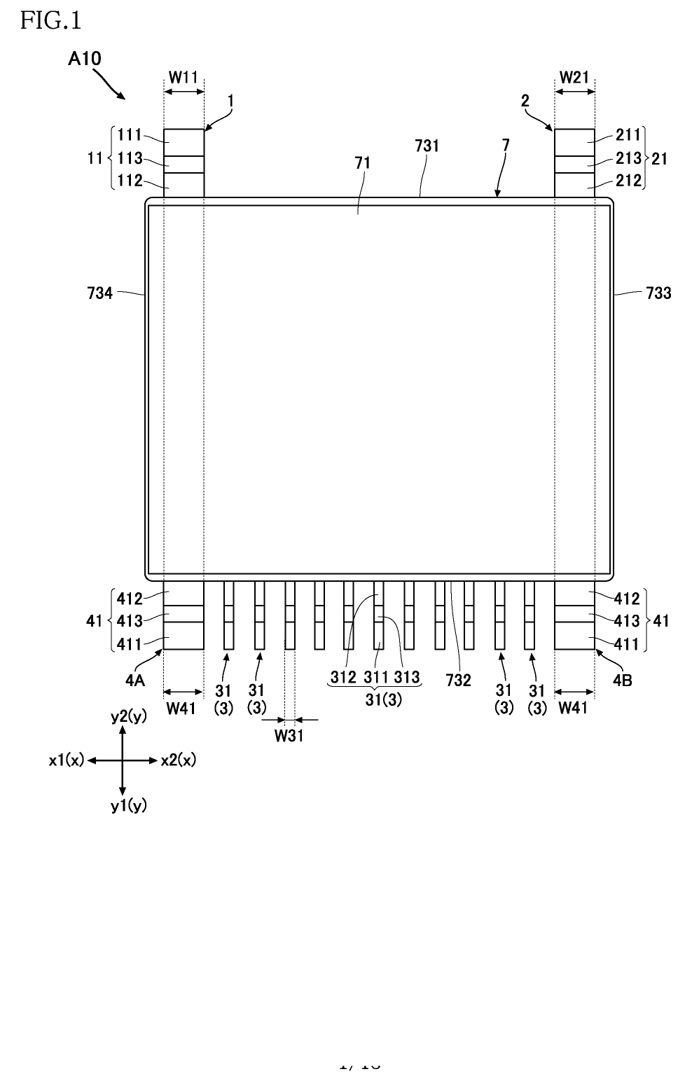

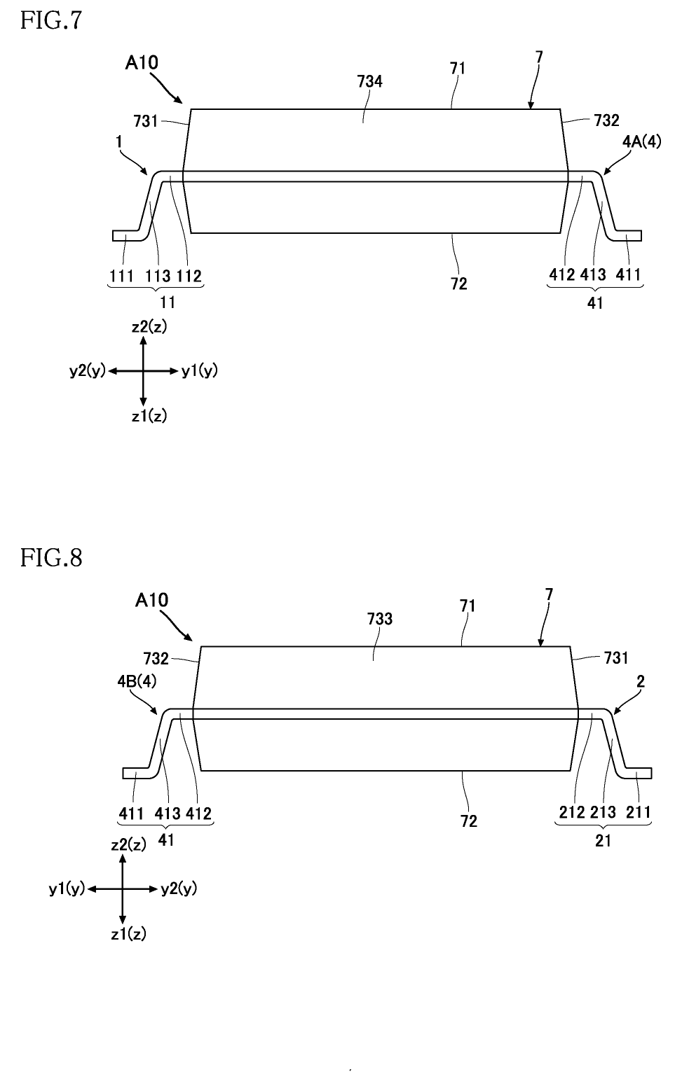

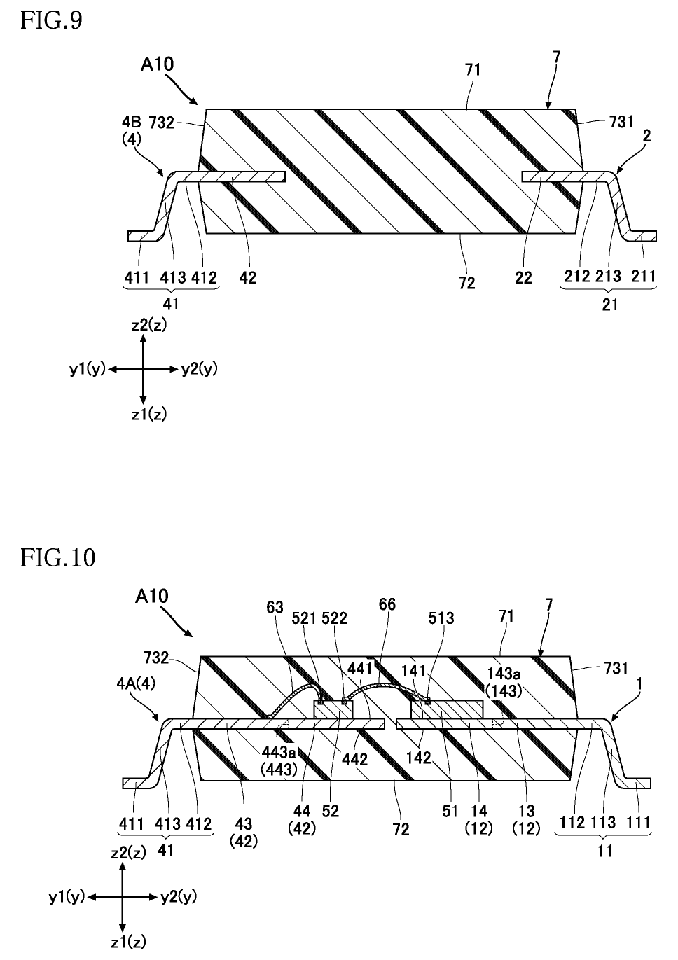

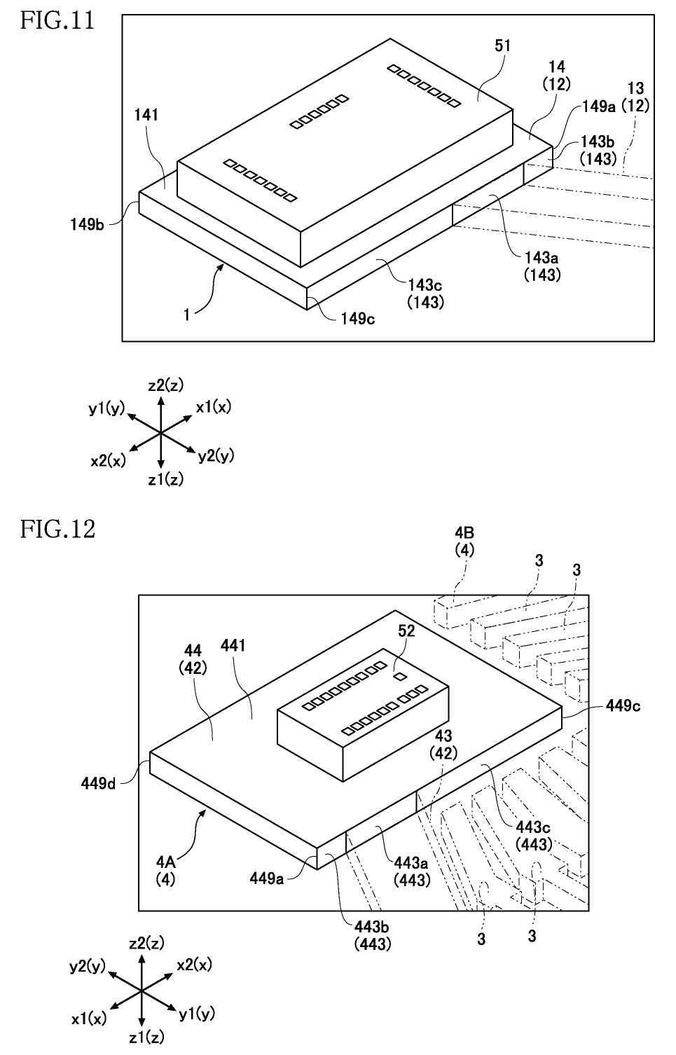

FIGS. 1 to 13 show an electronic device A10 according to a first embodiment. The electronic device A10 comprises a first lead 1, a second lead 2, a plurality of third leads 3, a pair of fourth leads 4, a first electronic component 51, a second electronic component 52, a plurality of connecting members 61 to 66, and a sealing resin 7. In the illustrated example, the electronic device A10 has eleven third leads 3, but the number of third leads 3 is not limited. The specific application of the electronic device A10 is not limited, but the electronic device A10 can, for example, detect the battery voltage of an electric vehicle. The electronic device A10 may be configured to detect other voltages of an electric vehicle instead of detecting the battery voltage. The electronic device A10 may also be configured to detect voltages related to industrial equipment, home appliances, or power supply devices instead of an electric vehicle. The electronic device A10 is a surface-mount type semiconductor package. In this embodiment, as shown in FIGS. 1 and 5 to 8, the electronic device A10 is of the SOP (Small Outline Package) type.

For convenience of description, mutually orthogonal directions such as thickness direction z, first direction y, and second direction x are referenced. The thickness direction z corresponds to the thickness of the electronic device A10 (or first electronic component 51). In this description, "plan view" refers to the view in/along the thickness direction z. The first direction y is orthogonal to the thickness direction z. The second direction x is orthogonal to both the thickness direction z and the first direction y. One side of the first direction y is referred to as the y1 side of the first direction y, and the other side is referred to as the y2 side of the first direction y. Likewise, one side of the second direction x is called the x1 side of the second direction x, and the other side is called the x2 side of the second direction x. Further, one side of the thickness direction z is called the z1 side of the thickness direction z, and the other side is called the z2 side of the thickness direction z. The z2 side of the thickness direction z is sometimes referred to as the upper side, and the z1 side of the thickness direction z is sometimes referred to as the lower side. Descriptions such as "upper," "lower," "upper side," "lower side," "upper surface," and "lower surface" indicate the relative positional relationship of each part, in the thickness direction z and do not necessarily define the relationship with respect to the direction of gravity.

The first lead 1, second lead 2, third leads 3, and fourth leads 4 contain a metal such as Cu (copper), Ni (nickel), Fe (iron), etc. The first lead 1, second lead 2, third leads 3, and fourth leads 4 are formed from the same lead frame (lead frame 9 described later). The first lead 1, second lead 2, third leads 3, and fourth leads 4 are formed by a processing technique selected from, for example, punching, bending, or etching, to a metal plate material. Where necessary, a plating layer composed of Ag (silver), Ni, Au (gold), etc., may be formed at appropriate locations of the first lead 1, second lead 2, third leads 3, and fourth leads 4.

The first lead 1, second lead 2, third leads 3, and fourth leads 4 conduct to the first electronic component 51 or second electronic component 52, while forming conduction paths in the electronic device A10. The first lead 1, second lead 2, third leads 3, and fourth leads 4 are spaced apart from each other. The first lead 1, second lead 2, third leads 3, and fourth leads 4 each have a portion covered by the sealing resin 7 and a portion exposed from the sealing resin 7.

The first lead 1 includes a first outer portion 11 and a first inner portion 12. The first outer portion 11 and the first inner portion 12 are connected to each other and integrally formed. The boundary between the first outer portion 11 and the first inner portion 12 overlaps with the periphery of the sealing resin 7 in plan view.

The first outer portion 11 is the portion of the first lead 1 exposed from the sealing resin 7. The first outer portion 11 protrudes from the sealing resin 7 toward the y2 side in the first direction y. The first outer portion 11 is rectangular in plan view, extending lengthwise in the first direction y. The first outer portion 11 is curved in a gull-wing shape as viewed in the second direction x. The dimension W11 (see FIG. 1) of the first outer portion 11 along the second direction x is not limited, but is, for example, between 0.1 mm and 1.5 mm, or a minimum of 0.1 mm and a maximum of 1.5 mm. The first outer portion 11 includes a first mounting portion 111, a first base portion 112, and a first intermediate portion 113.

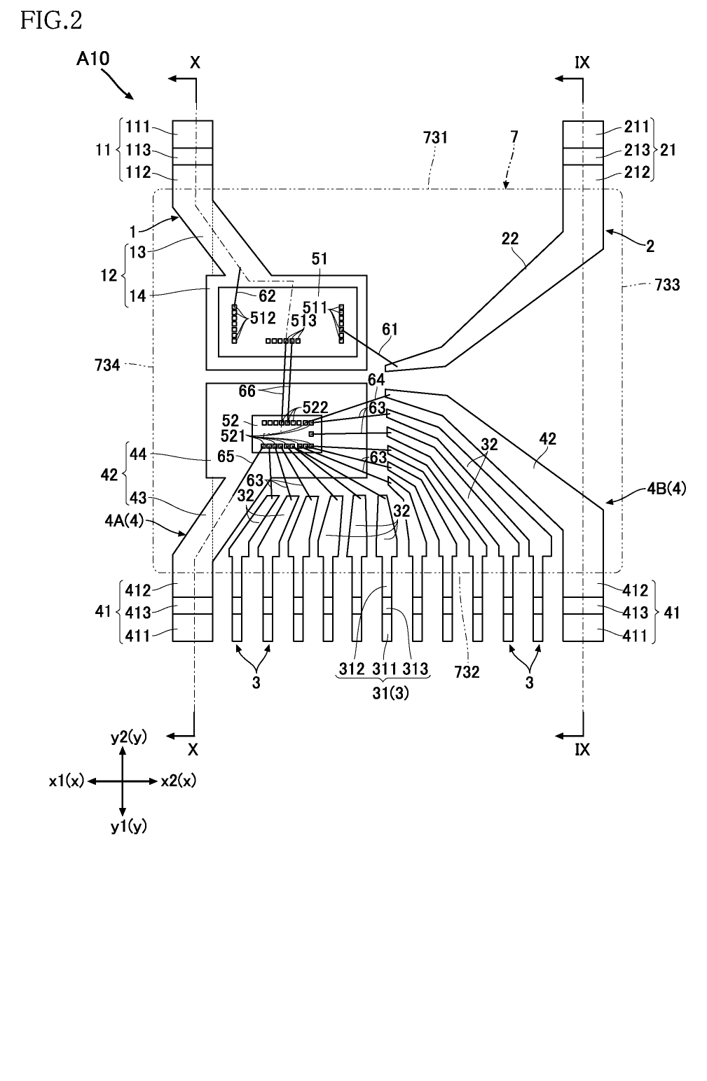

The first mounting portion 111 is the tip portion of the first outer portion 11. The first mounting portion 111 is the portion that is bonded to a circuit board when mounting the electronic device A10 onto the circuit board. As shown in FIGS. 1 and 2, the first mounting portion 111 is located at the end opposite the sealing resin 7 in the first direction y. The first mounting portion 111 is positioned farther from the sealing resin 7 in the first direction y than the first base portion 112 and the first intermediate portion 113. The first mounting portion 111 is positioned downward in the thickness direction z relative to the first base portion 112.

The first base portion 112 constitutes the root portion of the first outer portion 11. As shown in FIGS. 1 and 2, the first base portion 112 is located at the end of the first outer portion 11 closer to the sealing resin 7 in the first direction y. The first base portion 112 is positioned closer to the sealing resin 7 in the first direction y than the first mounting portion 111 and the first intermediate portion 113. The first base portion 112 is positioned above the first mounting portion 111 in the thickness direction z and protrudes from the central portion of the sealing resin 7 in the thickness direction z.

The first intermediate portion 113 connects the first mounting portion 111 and the first base portion 112 to each other. The first intermediate portion 113 is inclined relative to the first mounting portion 111 and the first base portion 112 as viewed in the second direction x. In this embodiment, the first intermediate portion 113 is also inclined relative to the thickness direction z.

The first inner portion 12 is the portion of the first lead 1 covered by the sealing resin 7. The first inner portion 12 extends from the first outer portion 11 to be located inside or within the sealing resin 7. The first inner portion 12 includes the first connecting portion 13 and the first die pad portion 14.

The first connecting portion 13 extends from the first outer portion 11 to be located inside the sealing resin 7. The first connecting portion 13 connects to the first die pad portion 14. The first connecting portion 13 connects the first inner portion 12 and the first die pad portion 14 to each other.

The first electronic component 51 is mounted on the first die pad portion 14 and supported by the first die pad portion 14. The first connecting portion 13 is connected to the first die pad portion 14, and the first die pad portion 14 is supported by the first connecting portion 13. The first die pad portion 14 is positioned on the y1 side of the first direction y relative to the first outer portion 11. The first outer portion 11 is positioned on the y2 side of the first direction y relative to the first die pad portion 14. In the second direction x, the center of the first die pad portion 14 is positioned on the x2 side of the second direction x relative to the center of the first outer portion 11. In the second direction x, the center of the first outer portion 11 is positioned on the x1 side of the second direction x relative to the center of the first die pad portion 14. In this embodiment, as shown in FIG. 2, as viewed in the first direction y, a portion of the first base portion 112 overlaps with the first die pad portion 14. Alternatively, as viewed in the first direction y, the entire first base portion 112 may overlap with the first die pad portion 14. Further, no part of the first base portion 112 may overlap with the first die pad portion 14. In other words, the entire first outer portion 11 may be positioned outward of the first die pad portion 14 (on the x1 side of the second direction x) in the second direction x. The first die pad portion 14 has an obverse surface 141, a reverse surface 142, and a first side surface 143.

The obverse surface 141 and reverse surface 142 are spaced apart from each other in the thickness direction z. The obverse surface 141 faces upward in the thickness direction z, and the reverse surface 142 faces downward in the thickness direction z. The first side surface 143 connects to the obverse surface 141 and reverse surface 142. The first side surface 143 faces the side where the first outer portion 11 is located (the y2 side in the first direction y) in the first direction y. The first connecting portion 13 is connected to the first side surface 143. The inclination angle α1 of the first connecting portion 13 relative to the first side surface 143 is not limited, but is, for example, at least 10° and at most 89°, or between 10° and 89°. In this embodiment, the inclination angle α1 is 45°, for example.

The first side surface 143 includes a connecting section 143a and two lateral sections 143b, 143c. The connecting section 143a connects to the first connecting portion 13 within the first side surface 143. The connecting section 143a is in contact with the first connecting portion 13. The lateral sections 143b and 143c are positioned on both sides of the connecting section 143a in the second direction x. The lateral section 143b is positioned on the x1 side relative to the connecting section 143a in the second direction x. The other lateral section 143c is positioned on the x2 side relative to the connecting section 143a in the second direction x (same side as the second lead 2). The lateral sections 143b and 143c are in contact with the sealing resin 7.

In the illustrated example, in the second direction x, the connecting section 143a is positioned on the x1 side relative to the center of the first side surface 143 in the second direction x. In the second direction x, the dimension of the lateral section 143b is smaller than the dimension of the lateral section 143c. Alternatively, in the second direction x, the connecting section 143a may be positioned at the center of the first side surface 143, or it may be positioned on the x2 side of the second direction x relative to the center of the first side surface 143. In the second direction x, the dimension of the lateral section 143b may be the same as the dimension of the other lateral section 143c, or it may be larger than the dimension of the lateral section 143c.

In the illustrated example, in plan view, the first die pad portion 14 is rectangular and has four corners. Specifically, the first die pad portion 14 has a first corner 149a, a second corner 149b, and two other corners 149c, 149d.

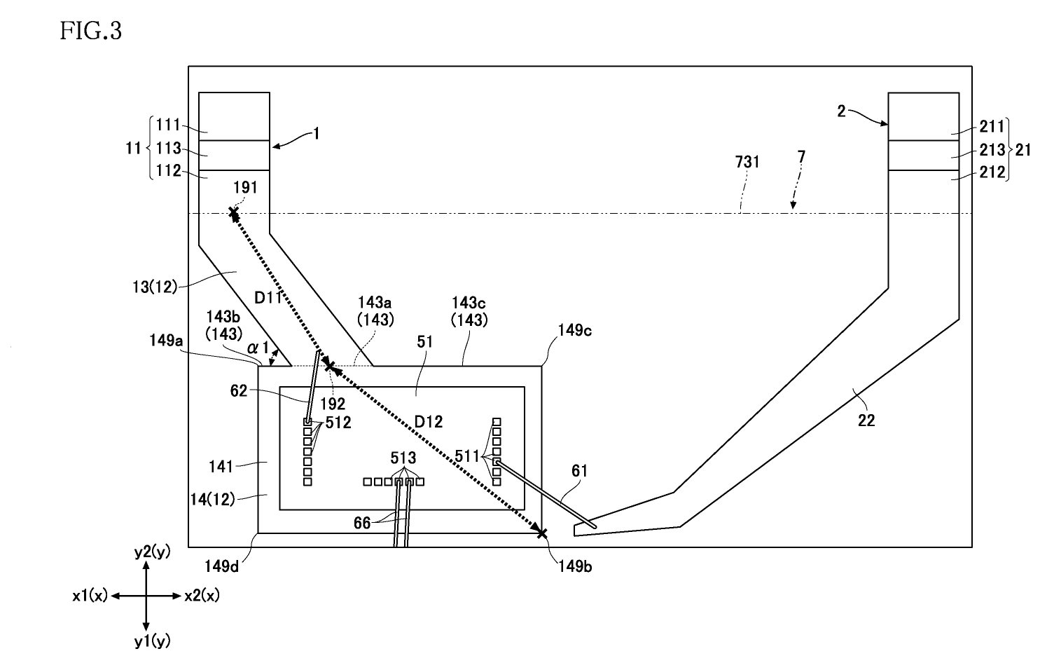

As shown in FIG. 3, in plan view, the first corner 149a is located on the y2 side of the first direction y and the x1 side of the second direction x. The first corner 149a is the closest of the four corners of the first die pad portion 14 to the first outer portion 11. The second corner 149b is located on the y1 side of the first direction y and the x2 side of the second direction x. The second corner 149b is diagonally opposite the first corner 149a. The second corner 149b is the farthest from the first outer portion 11 of the four corners of the first die pad portion 14. The corner 149c is located on the y2 side of the first direction y and the x2 side of the second direction x, and the corner 149d is located on the y1 side of the first direction y and the x1 side of the second direction x. The corner 149d is the diagonally opposite the corner 149c. The first corner 149a and the corner 149c correspond to the respective ends of the first side surface 143 in the second direction x.

The second lead 2 includes a second outer portion 21 and a second inner portion 22. The second outer portion 21 and the second inner portion 22 are connected to each other so as to be formed integral. In plan view, the boundary between the second outer portion 21 and the second inner portion 22 overlaps with the periphery of the sealing resin 7.

The second outer portion 21 is the portion of the second lead 2 exposed from the sealing resin 7. The second outer portion 21 protrudes from the sealing resin 7 toward the y2 side (the same side as the first outer portion 11) in the first direction y. In plan view, the second outer portion 21 has a rectangular shape elongated in the first direction y. In this embodiment, as viewed in plan, the second outer portion 21 is congruent with the first outer portion 11. However, unlike this, the first outer portion 11 and the second outer portion 21 may not be congruent with each other. The second outer portion 21 is bent in a gull-wing shape as viewed in the second direction x. The second outer portion 21 overlaps with the first outer portion 11 as viewed in the second direction x. The dimension W21 of the second outer portion 21 along the second direction x (see FIG. 1) is not limited, but is, for example, a minimum of 0.1 mm and a maximum of 1.5 mm. In this embodiment, the dimension W21 of the second outer portion 21 is the same as the dimension W11 of the first outer portion 11. Alternatively, the dimensions W21 and W11 may be different from each other. The second outer portion 21 includes a second mounting portion 211, a second base portion 212, and a second intermediate portion 213.

The second mounting portion 211 is the tip portion of the second outer portion 21. The second mounting portion 211 is bonded to the circuit board when mounting the electronic device A10 onto the circuit board. As shown in FIGS. 1 and 2, the second mounting portion 211 is located at the end opposite the sealing resin 7 in the first direction y. In the first direction y, the second mounting portion 211 is farther from the sealing resin 7 than the second base portion 212 and the second intermediate portion 213. In the thickness direction z, the second mounting portion 211 is located below the second base portion 212. In the thickness direction z, the second mounting portion 211 is located at the same position as the first mounting portion 111.

The second base portion 212 constitutes the root portion of the second outer portion 21. As shown in FIGS. 1 and 2, in the first direction y, the second outer portion 21 has a portion adjacent to the sealing resin 7, which corresponds to the second base portion 212. In the first direction y, the second base portion 212 is closer to the sealing resin 7 than the second mounting portion 211 and the second intermediate portion 213. In the thickness direction z, the second base portion 212 is positioned above the second mounting portion 211 and protrudes from the central portion of the sealing resin 7 in the thickness direction z. In the thickness direction z, the second base portion 212 is located at the same position as the first base portion 112.

The second intermediate portion 213 connects the second mounting portion 211 and the second base portion 212 to each other. The second intermediate portion 213 is inclined relative to the first mounting portion 111 and the first base portion 112 as viewed in the second direction x. In this embodiment, the second intermediate portion 213 is also inclined relative to the thickness direction z.

The second inner portion 22 is the portion of the second lead 2 covered by the sealing resin 7. The second inner portion 22 connects to the second outer portion 21 and extends from the second outer portion 21 into the sealing resin 7. Within the sealing resin 7, the second inner portion 22 extends from the second outer portion 21 toward the first die pad portion 14.

The third leads 3 each include a third outer portion 31 and a third inner portion 32, and thus the electronic device A10 is provided with a plurality of third outer portions 31 and a plurality of third inner portions 32. In each third lead 3, the third outer portion 31 and the third inner portion 32 are connected to each other and integrally formed. In plan view, the boundary between the third outer portion 31 and the third inner portion 32 overlaps with the periphery of the sealing resin 7. The description below regarding the third outer portion 31 and the third inner portion 32 may apply to all third leads 3 unless otherwise specified.

The third outer portion 31 is the portion exposed from the sealing resin 7. Each third outer portion 31 protrudes from the sealing resin 7 toward the y1 side of the first direction y (opposite the first outer portion 11 and second outer portion 21). Each third outer portion 31 is, in plain view, a long strip in the first direction y. The third outer portions 31 are arranged at equal intervals along the second direction x. Each third outer portion 31, as viewed in the second direction x, is curved in a gull-wing shape. The third outer portions 31, as viewed in the second direction x, overlap with each other. The dimension W31 of the third outer portion 31 along the second direction x (see FIG. 1) is not limited, but is, for example, a minimum of 0.15 mm and a maximum of 0.5 mm. The dimension W31 of the third outer portion 31 is smaller than the dimension W11 of the first outer portion 11 and the dimension W21 of the second outer portion 21. Each third outer portion 31 includes a third mounting portion 311, a third base portion 312, and a third intermediate portion 313, and thus the electronic device A10 is provided with a plurality of third mounting portions 311, a plurality of third base portions 312, and a plurality of third intermediate portions 313. Unless otherwise specified, the description below regarding the third mounting portion 311, third base portion 312 and third intermediate portion 313 may apply to all the third outer portions 31.

The third mounting portion 311 is the tip portion of the third outer portion 31. The third mounting portion 311 is bonded to the circuit board when mounting the electronic device A10 onto the circuit board. As shown in FIGS. 1 and 2, the third mounting portion 311 corresponds to the end opposite the sealing resin 7 in the first direction y. The third mounting portion 311 is farther from the sealing resin 7 in the first direction y than the third base portion 312 and the third intermediate portion 313. In the thickness direction z, the third mounting portion 311 is positioned below the third base portion 312. The third mounting portions 311 are positioned at the same location in the thickness direction z. The third mounting portions 311 are arranged at equal intervals along the second direction x.

In each third outer portion 31, the third base portion 312 constitutes the root portion of the third outer portion 31. As shown in FIGS. 1 and 2, the third base portion 312 corresponds to the end adjacent to the sealing resin 7 in the first direction y. The third base portion 312 is closer to the sealing resin 7 in the first direction y than the third mounting portion 311 and the third intermediate portion 313. In the thickness direction z, the third base portion 312 is positioned above the third mounting portion 311 and protrudes from the central portion of the sealing resin 7 in the thickness direction z. The third base portions 312 are positioned at the same location in the thickness direction z.

In each third outer portion 31, the third intermediate portion 313 connects the third mounting portion 311 and the third base portion 312 to each other. The third intermediate portion 313 is inclined relative to the third mounting portion 311 and the third base portion 312 as viewed in the second direction x. In this embodiment, the third intermediate portion 313 is also inclined relative to the thickness direction z.

In each third lead 3, the third inner portion 32 is the portion covered by the sealing resin 7. The third inner portion 32 connects to the third outer portion 31 and extends inward from the third outer portion 31 into the sealing resin 7. Within the sealing resin 7, the third inner portion 32 of each third lead 3 extends from the third outer portion 31 toward a portion (second die pad portion 44) of the fourth lead 4A, as described later.

The two fourth leads 4 are positioned on the both sides of the third leads 3 in the second direction x. In the following description, one of the fourth leads 4 may be referred to as "fourth lead 4A" and the other as "fourth lead 4B". The fourth lead 4A is positioned on the x1 side relative to the third leads 3 in the second direction x, and the fourth lead 4B is positioned on the x2 side relative to the third leads 3 in the second direction x. In the illustrated example, in plan view, the fourth lead 4A is congruent with the first lead 1, but these leads may not be congruent. In the illustrated example, in plan view, the fourth lead 4B is congruent with the second lead 2, but these leads may not be congruent. Each fourth lead 4 (4A, 4B) includes a fourth outer portion 41 and a fourth inner portion 42. In each fourth lead 4, the fourth outer portion 41 and the fourth inner portion 42 are connected to each other and integrally formed. In each fourth lead 4, the boundary between the fourth outer portion 41 and the fourth inner portion 42 overlaps with the periphery of the sealing resin 7 in plan view. Unless otherwise specified, the description below regarding the fourth outer portion 41 and the fourth inner portion 42 may apply to both fourth leads 4.

The fourth outer portion 41 is the portion of the fourth lead 4 exposed from the sealing resin 7. The fourth outer portion 41 protrudes from the sealing resin 7 toward the y1 side of the first direction y. The fourth outer portion 41 of the fourth lead 4A is positioned on the x1 side of the second direction x relative to the third outer portions 31. The fourth outer portion 41 of the fourth lead 4B is positioned on the x2 side of the second direction x relative to the third outer portions 31. Each fourth outer portion 41 is bent in a gull-wing shape as viewed in the second direction x. Each fourth outer portion 41 overlaps with the third outer portions 31 as viewed in the second direction x. Each fourth outer portion 41 is rectangular in plan view, elongated in the first direction y. In this embodiment, each fourth outer portion 41 is congruent with the first outer portion 11 in plan view. Alternatively, these outer portions may not be congruent with each other. The fourth outer portion 41 of the fourth lead 4A overlaps with the first outer portion 11 as viewed in the first direction y, and the fourth outer portion 41 of the fourth lead 4B overlaps with the second outer portion 21 as viewed in the first direction y. The dimension W41 (see FIG. 1) of each fourth outer portion 41 in the second direction x is not limited, but is, for example, a minimum of 0.1 mm and a maximum of 1.5 mm. In this embodiment, the dimension W41 of each fourth outer portion 41 is the same as the dimension W11 of the first outer portion 11 and the dimension W21 of the second outer portion 21. Alternatively, the dimension W41 of each fourth outer portion 41 may differ from the dimension W11 of the first outer portion 11 and the dimension W21 of the second outer portion 21. Each fourth outer portion 41 includes a fourth mounting portion 411, a fourth base portion 412, and a fourth intermediate portion 413. Unless otherwise specified, the description below regarding the fourth mounting portion 411, the fourth base portion 412, and the fourth intermediate portion 413 may apply to the fourth outer portion 41 of each fourth lead 4.

The fourth mounting portion 411 is the tip portion of the fourth outer portion 41. The fourth mounting portion 411 is bonded to the circuit board when mounting the electronic device A10 onto the circuit board. As shown in FIGS. 1 and 2, the fourth mounting portion 411 corresponds to the end opposite the sealing resin 7 in the first direction y. In the first direction y, the fourth mounting portion 411 is farther from the sealing resin 7 than the fourth base portion 412 and the fourth intermediate portion 413. In the thickness direction z, the fourth mounting portion 411 is positioned below the fourth base portion 412. The fourth mounting portion 411 is positioned at the same location as each third mounting portion 311 in the thickness direction z. The fourth mounting portion 411 of the fourth lead 4A is located on the x1 side of the third mounting portions 311 in the second direction x to be adjacent to the third mounting portions 311 in the second direction x. The fourth mounting portion 411 of the fourth lead 4B is located on the x2 side of the third mounting portions 311 in the second direction x to be adjacent to the third mounting portions 311 in the second direction x. The fourth mounting portion 411 of the fourth lead 4A overlaps with the first mounting portion 111 of the first lead 1 as viewed in the first direction y. The fourth mounting portion 411 of the fourth lead 4B overlaps with the second mounting portion 211 of the second lead 2 as viewed in the first direction y.

The fourth base portion 412 constitutes the root portion of the fourth outer portion 41. As shown in FIGS. 1 and 2, the fourth base portion 412 corresponds to the end portion of the fourth outer portion 41 adjacent to the sealing resin 7 in the first direction y. The fourth base portion 412 is closer to the sealing resin 7 than the fourth mounting portion 411 and the fourth intermediate portion 413 in the first direction y. In the thickness direction z, the fourth base portion 412 is positioned above the fourth mounting portion 411 and protrudes from the central portion of the sealing resin 7 in the thickness direction z. The fourth base portion 412 is positioned at the same location as each third base portion 312 in the thickness direction z.

The fourth intermediate portion 413 connects the fourth mounting portion 411 and the fourth base portion 412 to each other. The fourth intermediate portion 413 is inclined relative to the fourth mounting portion 411 and the fourth base portion 412 as viewed in the second direction x. In this embodiment, the fourth intermediate portion 413 is also inclined relative to the thickness direction z.

In each fourth lead 4, the fourth inner portion 42 is the portion covered by the sealing resin 7. The fourth inner portion 42 connects to the fourth outer portion 41 and extends inward from the fourth outer portion 41 into the sealing resin 7. In the fourth lead 4A, the fourth inner portion 42 includes a second connecting portion 43 and a second die pad portion 44. In the fourth lead 4B, the fourth inner portion 42 extends within the sealing resin 7 from the fourth outer portion 41 in a manner approaching the second die pad portion 44.

In the fourth lead 4A, the second connecting portion 43 extends from the fourth outer portion 41 into the sealing resin 7, and the second connecting portion 43 connects to the second die pad portion 44. In the fourth lead 4A, the second connecting portion 43 connects the fourth outer portion 41 and the second die pad portion 44 to each other.

The second electronic component 52 is mounted on the second die pad portion 44 and supported by the second die pad portion 44. The second die pad portion 44 is connected to the second connecting portion 43 and supported by the second connecting portion 43. The second die pad portion 44 is spaced apart from the first die pad portion 14. The first die pad portion 14 and the second die pad portion 44 are arranged side by side in the first direction y, with the second die pad portion 44 positioned on the y1 side relative to the first die pad portion 14 in the first direction y. The second die pad portion 44 is positioned on the y2 side relative to the respective fourth outer portions 41 in the first direction y. Each fourth outer portion 41 is positioned on the y1 side of the first direction y relative to the second die pad portion 44. In the second direction x, the center of the second die pad portion 44 is positioned on the x2 side of the second direction x relative to the center of the fourth outer portion 41 of the fourth lead 4A. In the second direction x, the center of the fourth outer portion 41 of the fourth lead 4A is positioned on the x1 side of the second direction x relative to the center of the second die pad portion 44. In this embodiment, as shown in FIG. 2, as viewed in the first direction y, a portion of the fourth base portion 412 of the fourth lead 4A overlaps with the second die pad portion 44. Alternatively, the entirety of the fourth base portion 412 of the fourth lead 4A may overlap with the second die pad portion 44 as viewed in the first direction y. Further, no part of the the fourth base portion 412 of the fourth lead 4A may overlap with the second die pad portion 44 as viewed in the first direction y. Then, in the fourth lead 4A, the fourth outer portion 41 may be positioned outwardly (on the x1 side in the second direction x) of the second die pad portion 44 in the second direction x. The second die pad portion 44 has an obverse surface 441, a reverse surface 442, and a second side surface 443.

The obverse surface 441 and reverse surface 442 are spaced apart in the thickness direction z. The obverse surface 441 faces upward in the thickness direction z, and the reverse surface 442 faces downward in the thickness direction z. The second side surface 443 connects to the obverse surface 441 and reverse surface 442. The second side surface 443 faces the side where the fourth outer portion 41 of the fourth lead 4A is located (the y1 side in the first direction y) in the first direction y. The second connecting portion 43 is connected to the second side surface 443. The inclination angle β1 of the second connecting portion 43 relative to the second side surface 443 is not limited, but is, for example, a minimum of 10° and a maximum of 89°. In this embodiment, the inclination angle β1 is 45°, for example.

The second side surface 443 includes a connecting section 443a and a pair of lateral sections 443b and 443c. The connecting section 443a is the portion of the second side surface 443 that connects to the second connecting portion 43. The connecting section 443a is in contact with the second connecting portion 43. The two lateral sections 443b and 443c are positioned on both sides of the connecting section 443a in the second direction x. The lateral section 443b is positioned on the x1 side relative to the connecting section 443a in the second direction x, and the lateral section 443c is positioned on the x2 side relative to the connecting section 443a in the second direction x (the same side as the fourth lead 4B). The lateral sections 443b and 443c are in contact with the sealing resin 7.

In the second direction x, the dimension of the lateral section 443b is smaller than the dimension of the lateral section 443c. Alternatively, the connecting section 443a may be positioned at the center of the second side surface 443, or it may be positioned on the x2 side relative to the center of the second side surface 443 in the second direction x. In the second direction x, the dimension of the lateral section 443b may be the same as the dimension of the lateral section 443c, or it may be larger than the dimension of the lateral section 443c.

In the illustrated example, in plan view, the second die pad portion 44 is rectangular and has four corners 449a, 449b, 449c, and 449d.

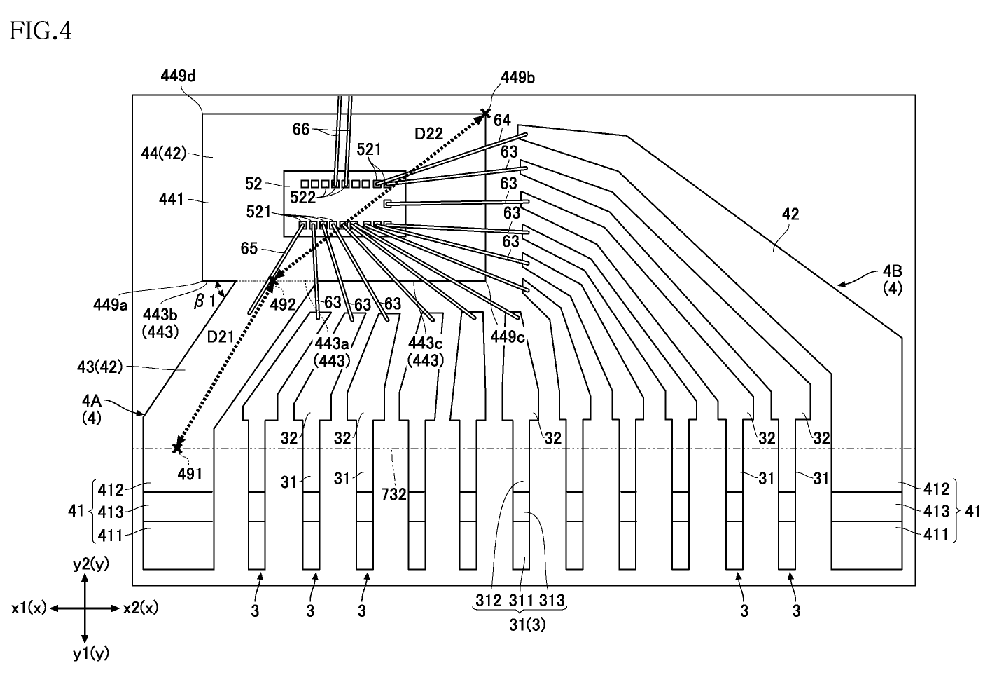

As shown in FIG. 4, the corner 449a is located on the y1 side of the first direction y and the x1 side of the second direction x in plan view. Of the four corners, the corner 449a is closest to the fourth outer portion 41 of the fourth lead 4A. In plan view, the corner 449b is located on the y2 side of the first direction y and the x2 side of the second direction x. The corner 449b is diagonally opposite the corner 449a. Of the four corners, the corner 449b is the farthest from the fourth outer portion 41 of the fourth lead 4A. In plan view, the corner 449c is located on the y1 side of the first direction y and the x2 side of the second direction x. In plan view, the corner 449d is located on the y2 side of the first direction y and the x1 side of the second direction x. The corner 449d is the diagonal opposite of the corner 449c. The corner 449a and the corner 449c are the respective ends of the second side surface 443 in the second direction x.

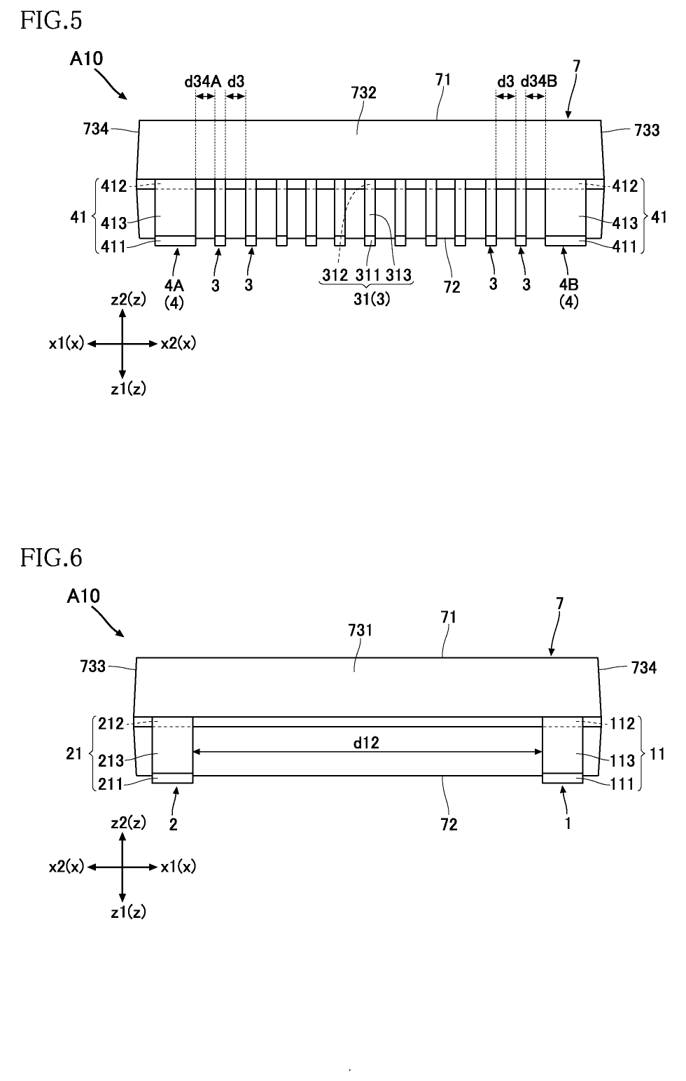

In the electronic device A10, the first outer portion 11 and the first inner portion 12 are adjacent to each other with a spacing d12 (see FIG. 6) in the second direction x. The third outer portions 31 are arranged with a placement spacing d3 (see FIG. 5) in the second direction x. In the second direction x, the spacing d12 (see FIG. 6) between the first outer portion 11 and the first inner portion 12 is larger than the placement spacing d3 (see FIG. 5) of the third outer portions 31. Specifically, the spacing d12 is at least 10 times the placement spacing d3 and at most 20 times the placement spacing d3. In this embodiment, the spacing d12 is, for example, at least 5 mm and at most 10 mm, and the placement spacing d3 is, for example, at least 0.25 mm and at most 5 mm. When the potential difference between the first outer portion 11 and the second outer portion 21 is approximately 800 V, the spacing d12 between the first outer portion 11 and the second outer portion 21 is preferably 4 mm or greater to suppress short circuits. In the second direction x, the spacing d34A (see FIG. 5) between the fourth outer portion 41 of the fourth lead 4A and the adjacent third outer portion 31, and the spacing d34B (see FIG. 5) between the fourth outer portion 41 of the fourth lead 4B and the adjacent third outer portion 31, are each the same as the placement spacing d3.

In the electronic device A10, the shapes and relative positions of the first die pad portion 14, the second die pad portion 44, the first inner portion 12, the second inner portion 22, the third inner portions 32, the fourth inner portions 42 are not limited to those of the illustrated examples, and may be appropriately modified according to the specifications of the electronic device A10.

The first electronic component 51 and the second electronic component 52 are elements that perform electrical functions within the electronic device A10. The specific functions of the first electronic component 51 and the second electronic component 52 are not limited. In the embodiment, the first electronic component 51 and the second electronic component 52 may have the function to detect voltage.

The first electronic component 51 is bonded to the first die pad portion 14 using an unillustrated bonding material (e.g., solder or sintered silver). In the illustrated example, in plan view, the connecting section 143a of the first die pad portion 14 is spaced apart from the first electronic component 51 in the first direction y. In this embodiment, the first electronic component 51 outputs, to the second electronic component 52, a first signal corresponding to the potential of the first lead 1 and a second signal corresponding to the potential of the second lead 2. The first electronic component 51 has an upper surface in the thickness direction z provided with a plurality of electrodes 511, 512, 513.

The second electronic component 52 is bonded to the second die pad portion 44 using an unillustrated bonding material (e.g., solder or sintered silver). In the illustrated example, in plan view, the connecting section 443a of the second die pad portion 44 is spaced apart from the second electronic component 52 in the first direction y. In this embodiment, the second electronic component 52 receives a first signal and a second signal from the first electronic component 51 and outputs a third signal corresponding to the potential difference between the first lead 1 and the second lead 2. The second electronic component 52 outputs a detection signal (the third signal) regarding the voltage applied between the first lead 1 and the second lead 2. The second electronic component 52 has an upper surface in the thickness direction z provided with a plurality of electrodes 521, 522.

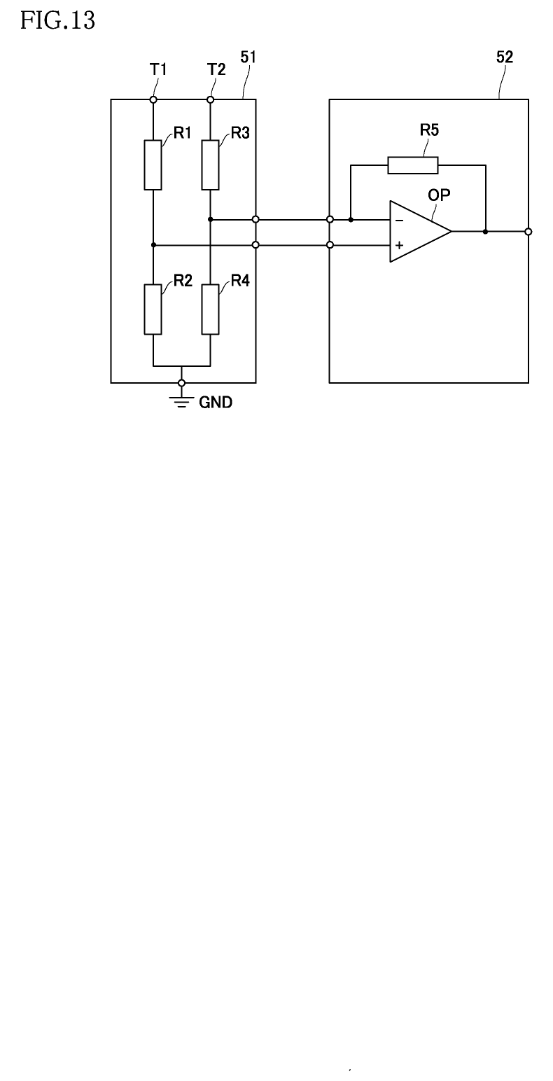

In the electronic device A10, the first electronic component 51 and the second electronic component 52 have, for example, the circuit configuration shown in FIG. 13. As seen from FIG. 13, the first electronic component 51 includes a plurality of resistors R1 to R4, and the second electronic component 52 includes an operational amplifier OP and a resistor R5. The circuit configurations of the first electronic component 51 and the second electronic component 52 are not limited to those shown in FIG. 13.

The resistors R1, R2 are connected in series with each other. The resistors R1, R2 divide the voltage applied to the terminal T1 (the potential difference between the terminal T1 and the ground GND at which the reference potential is applied). In this embodiment, the terminal T1 may correspond to the electrodes 512. The connection point of the resistors R1 and R2 is connected to the non-inverting input terminal of the operational amplifier OP. The resistors R3 and R4 are connected in series with each other. The resistors R3 and R4 divide the voltage applied to the terminal T2 (the potential difference between the terminal T2 and the ground GND). In this embodiment, the terminal T2 may correspond to the electrodes 511. The connection point of the resistors R3 and R4 is connected to the inverting input terminal of the operational amplifier OP. When the electronic device A10 is used for detecting the voltage of a battery installed in an electric vehicle, one of the terminals T1, T2 is electrically connected to the terminal of high-potential side of the battery, and the other is electrically connected to the terminal of low-potential side of the battery.

The operational amplifier OP receives a first signal related to the potential at the terminal T1 (in this embodiment, a signal corresponding to the result of the voltage division with respect to the voltage at the terminal T1) and a second signal related to the potential at the terminal T2 (in this embodiment, a signal corresponding to the result of the voltage division with respect to the voltage at the terminal T2). The operational amplifier OP outputs a third signal related to the potential difference between the terminals T1 and T2. The resistor R5 is a component (feedback resistor) for determining the amplification gain of the operational amplifier OP. One end of the resistor R5 is connected to the inverting input terminal of the operational amplifier OP, and the other end is connected to the output terminal of the operational amplifier OP. The second electronic component 52 may not include the resistor R5.

The connecting members 61 to 66 each electrically connect at least two mutually separated portions. In the illustrated example, the connecting members 61 to 66 are bonding wires. The connecting members 61 to 66 may be plate-shaped metal members instead of bonding wires. The connecting members 61 to 66 each contain either Au, Al (aluminum), or Cu.

As shown in FIG. 2, the connecting member 61 is bonded to one electrode 511 of the first electronic component 51 and to the second inner portion 22, electrically connecting the first electronic component 51 and the second lead 2. The second outer portion 21 of the second lead 2 is conductively connected to the first electronic component 51 via the second inner portion 22 and the connecting member 61.

The connecting member 62 is bonded to one electrode 512 of the first electronic component 51 and to the first connecting portion 13 (first inner portion 12), as shown in FIG. 2, electrically connecting the first electronic component 51 and the first lead 1. The first outer portion 11 of the first lead 1 conducts to the first electronic component 51 via the first connecting portion 13 and the connecting member 62.

The connecting members 63 are each bonded to one electrode 521 of the second electronic component 52 and one of the third inner portions 32, as shown in FIG. 2. Thus, the second electronic component 52 is electrically connected to the third leads 3. The third outer portion 31 of each third lead 3 conducts to the second electronic component 52 via the corresponding third inner portion 32 and the corresponding connecting member 63.

The connecting member 64 is bonded to one electrode 521 of the second electronic component 52 and to the fourth inner portion 42 of the fourth lead 4B, as shown in FIG. 2, electrically connecting the second electronic component 52 and the fourth lead 4B. The fourth outer portion 41 of the fourth lead 4B conducts to the second electronic component 52 via the fourth inner portion 42 of the fourth lead 4B and the connecting member 64.

The connecting member 65 is bonded to one electrode 521 of the second electronic component 52 and to the second connecting portion 43 (fourth inner portion 42), as shown in FIG. 2, electrically connecting the second electronic component 52 and the fourth lead 4A. The fourth outer portion 41 of the fourth lead 4A conducts to the second electronic component 52 via the second connecting portion 43 of the fourth lead 4A and the connecting member 65.

As shown in FIG. 2, the connecting members 66 are each bonded to one electrode 513 of the first electronic component 51 and one electrode 522 of the second electronic component 52, electrically connecting the first electronic component 51 and the second electronic component 52. The connecting members 66 serve as transmission paths for the aforementioned first signal and second signal.

The sealing resin 7 covers a portion of the first lead 1, a portion of the second lead 2, a portion of each third lead 3, and a portion of each fourth lead 4, while also covering the first electronic component 51, the second electronic component 52, and the connecting members 61 to 66. The sealing resin 7 contains, for example, an insulating material such as an epoxy resin. Preferably, the sealing resin 7 may be made of a resin material having a comparative tracking index (CTI) of at least 600V. The method for forming the sealing resin 7 is not limited, but mold forming may be used, for example. The sealing resin 7 has, for example, a rectangular prism shape. In the second direction x, the sealing resin 7 has dimensions of, for example, a minimum of 5 mm and a maximum of 10 mm. In the first direction y, the sealing resin 7 has dimensions of, for example, a minimum of 3 mm and a maximum of 13 mm. The sealing resin 7 has a resin obverse surface 71, a resin reverse surface 72, a first resin side surface 731, a second resin side surface 732, and two resin side surfaces 733, 734.

The resin obverse surface 71 and the resin reverse surface 72 are spaced apart from each other in the thickness direction z. The resin obverse surface 71 faces the z2 side in the thickness direction z, and the resin reverse surface 72 faces the z1 side in the thickness direction z. The resin obverse surface 71 is the upper surface of the sealing resin 7, and the resin reverse surface 72 is the lower surface of the sealing resin 7.

The first resin side surface 731 and the second resin side surface 732 are spaced apart from each other in the first direction y. The first resin side surface 731 faces the y2 side of the first direction y, and the second resin side surface 732 faces the 1 yide of the first direction y. The resin side surfaces 733 and 734 are spaced apart from each other in the second direction x. The resin side surface 733 faces the x2 side of the second direction x, and the resin side surface 734 faces the x1 side of the second direction x.

As shown in FIGS. 1 to 3 and FIGS. 6 to 10, the first outer portion 11 and the second outer portion 21 protrude from the first resin side surface 731. As shown in FIGS. 1, 2, 4, 5, and 7 to 10, the third outer portions 31 of the third leads 3 and the fourth outer portions 41 of the fourth leads 4 protrude from the second resin side surface 732.

In the electronic device A10, the sum of the distance D11 from the first connection point 191 to the second connection point 192 (see FIG. 3) and the distance D12 from the second connection point 192 to the second corner 149b (see FIG. 3) is smaller than when the first connecting portion 13 is located so as to touch the first corner 149a (the corner closest to the first outer portion 11) of the first die pad portion 14. As shown in FIG. 3, the first connection point 191 is the center of the boundary ("first boundary") between the first inner portion 12 and the first outer portion 11. In this embodiment, in plan view, the first boundary is a line segment parallel to the second direction x, and the center of the first boundary is the midpoint of this line segment. The second connection point 192, as shown in FIG. 3, is the center of the boundary ("second boundary") between the first connecting portion 13 and the first die pad portion 14. In this embodiment, in plan view, the second boundary is a line segment parallel to the second direction x, and the center of the second boundary is the midpoint of this line segment. The distance D11 is the shortest length on the first connecting portion 13 from the first connection point 191 to the second connection point 192. The distance D12 is the shortest length on the first die pad portion 14 from the second connection point 192 to the second corner 149b.

In the electronic device A10, the sum of the distance D21 from connection point 491 to the connection point 492 (see FIG. 4) And the distance D22 from the connection point 492 to the corner 449b (see FIG. 4) is shorter than when the second connecting portion 43 is located so as to touch the corner 449a (the corner closest to the fourth outer portion 41 of the fourth lead 4A) of the second die pad portion 44. As shown in FIG. 4, the connection point 491 is the center of the boundary ("third boundary") between the fourth inner portion 42 and the fourth outer portion 41 of the fourth lead 4A. In this embodiment, in plan view, the third boundary is a line segment parallel to the second direction x, and the center of the third boundary is the midpoint of that line segment. The connection point 492, as shown in FIG. 4, is the center of the boundary ("fourth boundary") between the second connecting portion 43 and the second die pad portion 44. In this embodiment, in plan view, the fourth boundary is a line segment parallel to the second direction x, and the center of the fourth boundary is the midpoint of said line segment. The distance D21 is the shortest length on the second connecting portion 43 from the connection point 491 to the connection point 492, and the distance D22 is the shortest length on the second die pad portion 44 from the connection point 492 to the corner 449b.

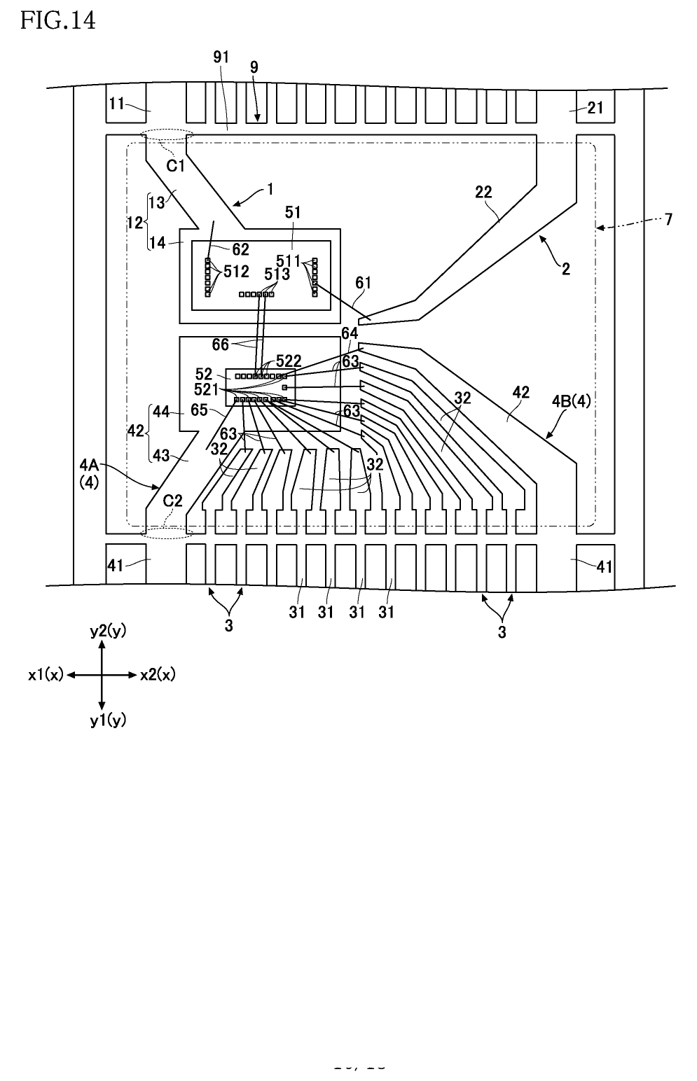

FIG. 14 shows one process for manufacturing the electronic device A10. FIG. 14 shows the state prior to forming the sealing resin 7. In the manufacturing process of the electronic device A10, as shown in FIG. 14, the first lead 1, the second lead 2, the third leads 3, and the fourth leads 4 are interconnected by tie bars 91 and are contained within a single lead frame 9. The tie bars 91 connect, for example, the first outer portion 11 of the first lead 1, the second outer portion 21 of the second lead 2, the third outer portions 31 of the third leads 3, and the fourth outer portions 41 of the fourth leads 4. In this state of the lead frame 9, the first inner portion 12 is supported by the tie bars 91 via a connection part C1 shown in FIG. 14. The fourth inner portion 42 of the fourth lead 4A is supported by the tie bars 91 via a connection part C2 shown in FIG. 14.

In the manufacturing process of the electronic device A10, the first electronic component 51 and the second electronic component 52 are mounted (bonded) on the lead frame 9 shown in FIG. 14, and the connecting members 61 to 66 are provided (wire bonded), and then the sealing resin 7 is formed, for example, by mold forming. Thereafter, the first lead 1, the second lead 2, the third leads 3, and the fourth leads 4 are severed from the tie bars 91, and the first outer portion 11, the second outer portion 21, the third outer portions 31, and the fourth outer portions 41 are bent as required to produce the electronic device A10.

The electronic device A10 may have the following functions and advantages.

In the electronic device A10, in the second direction x, the center of the first outer portion 11 is positioned on the x1 side relative to the center of the first die pad portion 14. That is, the first outer portion 11 is offset with respect to the first die pad portion 14 toward a certain side in the second direction x. According to such a positional relationship between the first outer portion 11 and the first die pad portion 14, the first connecting portion 13 may be connected to the first die pad portion 14 such that it touches one of the edges of the first die pad portion 14 spaced apart in the second direction x. In this case, however, the connecting position of the first connecting portion 13 to the first die pad portion 14 is the farthest from the center of the first die pad portion 14. On the other hand, in the electronic device A10, the first side surface 143 of the first die pad portion 14 is configured to include a connecting section 143a for the first connecting portion 13 and a pair of lateral sections 143b, 143c arranged on both sides of the connecting section 143a in the second direction x. According to this configuration, the connecting position of the first connecting portion 13 to the first die pad portion 14 is more centrally located in the second direction x relative to the edge of the first die pad portion 14. That is, the connecting position is closer to the center of the first die pad portion 14. Accordingly, in the electronic device A10, the stress applied to the connecting portion between the first connecting portion 13 and the first die pad portion 14 due to the weight of the first die pad portion 14 can be reduced. Thus, in the electronic device A10, deformation of the first lead 1, or deformation of the lead frame, can be reduced.

The advantages described above may also apply to the second die pad portion 44. Specifically, in the electronic device A10, the second side surface 443 includes a connecting section 443a connected to the second connecting portion 43 and a pair of lateral sections 443b, 443c arranged on both sides of the connecting section 443a in the second direction x. The connecting position of the second connecting portion 43 relative to the second die pad portion 44 is closer to the center of the second die pad portion 44. Thus, in the electronic device A10, the stress applied to the connecting portion between the second connecting portion 43 and the second die pad portion 44 due to the weight of the second die pad portion 44 can be reduced, thereby making it possible to reduce deformation of the fourth lead 4A, or deformation of the lead frame.

According to the electronic device A10 the sum of the distance D11 and the distance D12 is smaller than when the first connecting portion 13 is connected so as to touch the first corner 149a (the corner closest to the first outer portion 11) of the first die pad portion 14. This configuration may reduce deformation of the first lead 1. As shown in FIG. 14, during the manufacturing of the electronic device A10, the first inner portion 12 is supported by the tie bars 91 via the connection part C1. In this case, an external force applied to the first die pad portion 14 may generate a bending moment on the connection part C1. During the manufacturing process of the electronic device A10, external forces may be applied to the first die pad portion 14, for example, during the transport of the lead frame 9, during the bonding of the first electronic component 51 to the first die pad portion 14, or during the bonding of the connecting members 61, 62 to the first electronic component 51. The larger the bending moment, the greater the possibility of deformation (bending) at the connection part C1. However, as the sum of the distance D11 and the distance D12 becomes smaller, the bending moment will be smaller. As noted above, in the electronic device A10, the sum of the distances D11 and D12 is smaller than, for example, when the first connecting portion 13 is located so as to touch the first corner 149a (the corner closest to the first outer portion 11) of the first die pad portion 14. Thus, the electronic device A10 is advantageous to reducing the bending moment to be applied to the connection part C1, and thereby reducing deformation of the first lead 1.

The above-mentioned advantage may also apply to the second die pad portion 44. Specifically, in the electronic device A10, for example, the sum of the distances D21 and D22 is smaller than when the second connecting portion 43 is connected so as to touch the corner 449a of the second die pad portion 44 (the corner closest to the fourth outer portion 41 of the fourth lead 4A). Thus, in the electronic device A10, the bending moment acting on the connection part C2 can be reduced, thereby reducing deformation of the fourth lead 4A.

In the electronic device A10, the side surfaces of the first die pad portion 14, except for the connecting section 143a, are in contact with the sealing resin 7. The side surfaces of the first die pad portion 14 are the surfaces of the first die pad portion 14 that connect to and are sandwiched between the obverse surface 141 and the reverse surface 142, where one of these surfaces is the first side surface 143. In the present configuration, only the first connecting portion 13 is connected to the first die pad portion 14 in a manner such that the first die pad portion 14 is supported solely by the first connecting portion 13. Thus, the stress on the connection part C1 may be large. By the electronic device A10, it is desirable that the sum of the distances D11 and D12 is small, thereby reducing deformation of the first lead 1.

In the electronic device A10, the inclination angle α1 of the first connecting portion 13 relative to the first side surface 143 is at least 10° and at most 89°. For example, if the inclination angle α1 is less than 10° (the lower limit value mentioned above), the first connecting portion 13 connects to the first side surface 143 at an acute angle. Consequently, strength at the second boundary decreases, increasing the likelihood of deformation occurring at the second boundary. If the inclination angle α1 is greater than 89° (the upper limit mentioned above), the second boundary is closer to the first corner 149a. In this case, the sum of distances D11 and D12 increases, raising the likelihood of deformation occurring at the connection part C1. In the electronic device A10, setting the inclination angle α1 within the above range can properly reduce deformation at the second boundary and deformation at the connection part C1, making it preferable for reducing deformation of the first lead 1. In an embodiment, setting the inclination angle α1 to 45° can effectively suppress deformation at the second boundary and deformation at the connection part C1, making it preferable for deformation reduction in the first lead 1.

The above advantages may also apply to the second die pad portion 44. Specifically, in the electronic device A10, the inclination angle β1 of the second connecting portion 43 relative to the second side surface 443 is at least 10° and at most 89°. This allows for a suitable reduction in deformation at the fourth boundary and at the connection part C2, making it advantageous for reducing deformation of the fourth lead 4A. In particular, setting the inclination angle β1 to 45° can achieve a proper reduction in deformation at the fourth boundary and at the connection part C2, thereby reducing deformation of the fourth lead 4A.

In the electronic device A10, in the second direction x, the connecting section 143a is positioned on the x1 side of the second direction x relative to the center of the first side surface 143 (i.e., the side where the center of the first outer portion 11 is located, or the side where the first corner 149a is located). According to this configuration, the inclination angle α1 of the first connecting portion 13 relative to the first side surface 143 may be set to a minimum of 30° and a maximum of 45°.

In the electronic device A10, the connecting section 443a is positioned on the x1 side of the second direction x relative to the center of the second side surface 443 (the side where the center of the fourth outer portion 41 of the fourth lead 4A is located, or the side where the corner 449a is located). According to this configuration, the inclination angle β1 of the second connecting portion 43 relative to the second side surface 443 may be set to a minimum of 30° and a maximum of 45°. Advantageously, the electronic device A10 is also configured to ensure that the plurality of third leads 3 are provided between the two fourth leads 4.

In the electronic device A10, the first outer portion 11 and the second outer portion 21 are adjacent to each other (i.e., with no other lead portions present) in the second direction x with a spacing d12 between them, and the third outer portions 31 are arranged in the second direction x with an placement spacing d3 between them. The spacing d12 is greater than the placement spacing d3. According to this configuration, the creepage distance (distance along the surface of the sealing resin 7) between the first outer portion 11 and the second outer portion 21 is greater than the creepage distance between adjacent third outer portions 31. Consequently, even when a high voltage is applied between the first outer portion 11 and the second outer portion 2, discharge between the first outer portion 11 and the second outer portion 21 is less likely to occur. As such, the electronic device A10 can enable reduction of discharge between the first outer portion 11 and the second outer portion 21 while achieving miniaturization of the device. In other words, the electronic device A10 possesses a preferred package structure advantageous for reducing discharge between the first outer portion 11 and the second outer portion 21.

Hereinafter, other embodiments/variations of the present disclosure will be described. It should be noted that components in the embodiments/variations of the present disclosure described above and below may be combined provided that no technical contradictions arise.

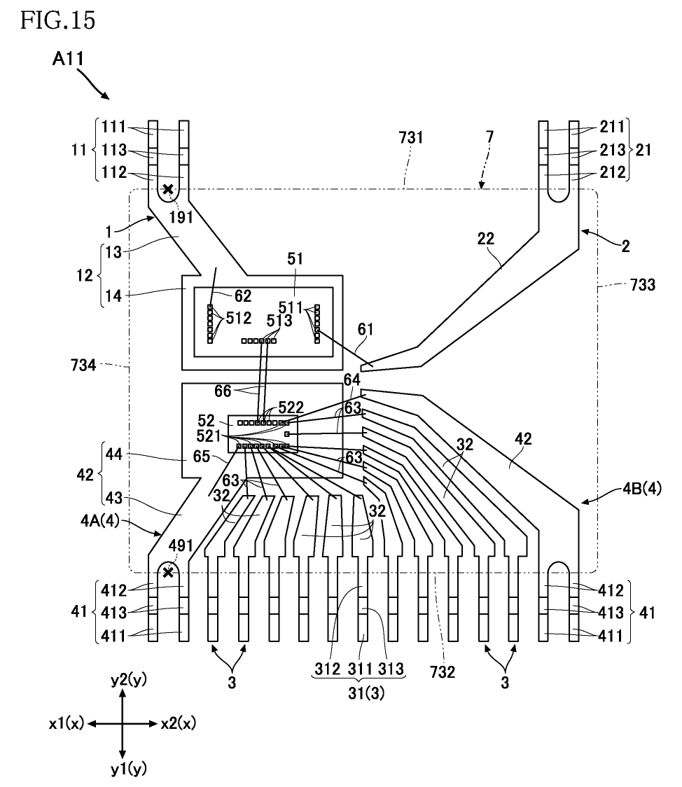

FIGS. 15 to 17 show an electronic device A11 according to a first variation of the first embodiment. The electronic device A11 may differ from the electronic device iA10 n configurations of the first lead 1, the second lead 2, and the fourth leads 4.

As shown in FIGS. 15 and 17, the first lead 1 of the electronic device A11 includes two first outer portions 11 spaced apart from each other. Unlike the illustrated example, three or more first outer portions 11 may be provided. Each first outer portion 11 includes a first mounting portion 111, a first base portion 112, and a first intermediate portion 113. As shown in FIG. 17, the two first outer portions 11 are adjacent to each other with a spacing d1 in the second direction x. The spacing d1 may be the same as the above placement spacing d3, for example, but may also be different. Due to this configuration, the first inner portion 12 of the first lead 1 has a bifurcated end connected to the respective first outer portions 11. The two first outer portions 11 are electrically connected to each other via the first inner portion 12, thus having the same potential. Since the first lead 1 includes two first outer portions 11, the first lead 1 has two first boundaries as noted above. In the illustrated case, the first connection point 191 may be the midpoint between the two first boundaries, as shown in FIG. 15.

As shown in FIGS. 15 and 17, the second lead 2 of the electronic device A11 includes two second outer portions 21 spaced apart from each other. Unlike the illustrated example, three or more second outer portions 21 may be provided. Each second outer portion 21 includes a second mounting portion 211, a second base portion 212, and a second intermediate portion 213. As shown in FIG. 17, the two second outer portions 21 are adjacent with a spacing d2 in the second direction x. The spacing d2 may be the same as the aforementioned placement spacing d3, for example, but may also be different. Due to this configuration, the second inner portion 22 of the second lead 2 has a bifurcated end connected to the respective second outer portions 21. The two second outer portions 21 are electrically connected to each other via the second inner portion 22 and thus have the same potential.

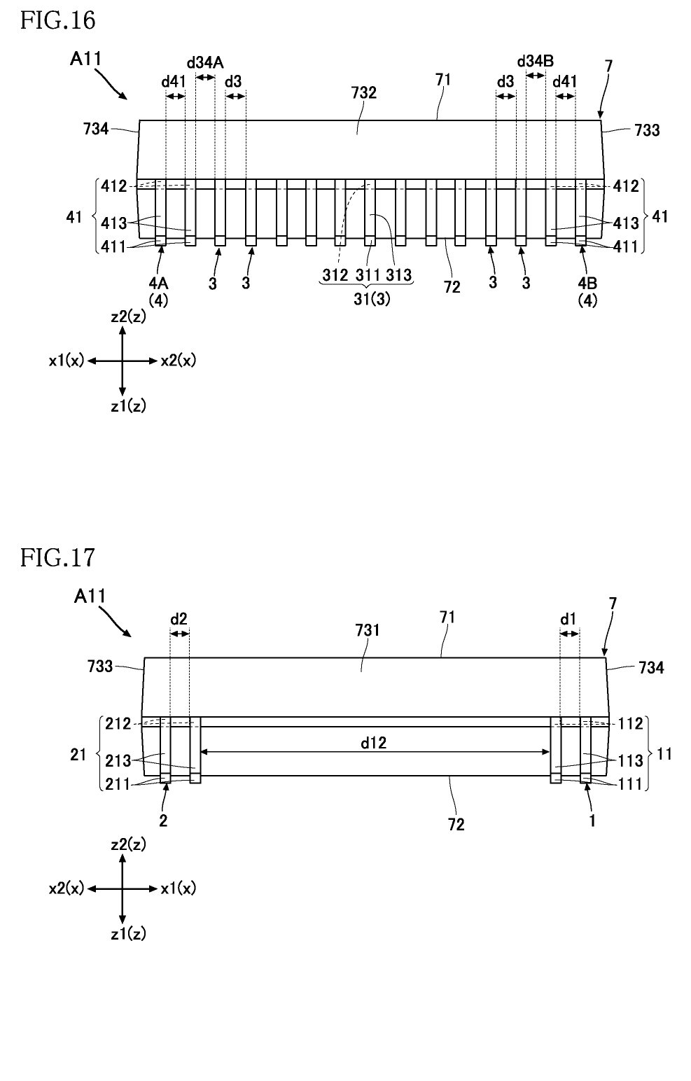

As shown in FIGS. 15 and 16, each fourth lead 4 of the electronic device A11 includes two fourth outer portions 41 spaced apart from each other. Unlike the illustrated example, three or more fourth outer portions 41 may be provided. In each fourth lead 4, the fourth outer portions 41 each include a fourth mounting portion 411, a fourth base portion 412, and a fourth intermediate portion 413. As shown in FIG. 16, the two fourth outer portions 41 are adjacent to each other with a spacing d41 in the second direction x. The spacing d41 may be the same as the aforementioned placement spacing d3, for example, but may also be different. Due to this configuration, the fourth inner portion 42 of each fourth lead 4 has a bifurcated end connecting to the respective fourth outer portions 41. In each fourth lead 4, the two fourth outer portions 41 are electrically connected to each other via the fourth inner portion 42, thus having the same potential. Since the fourth lead 4A includes two fourth outer portions 41, the fourth lead 4A has two third boundaries as noted above. In this case, the connection point 491 may be the midpoint between the two third boundaries, as shown in FIG. 15.

In the electronic device A11, similar to the electronic device A10, deformation of the first lead 1 and deformation of the fourth lead 4A, i.e., deformation of the lead frame, can be reduced. Furthermore, the electronic device A11 can achieve the same effects as those of the electronic device A10.

In the first variation above, each of the first lead 1, second lead 2, and fourth leads 4 has a bifurcation in the sealing resin 7. Alternatively, as with the electronic device A10, at least one of these leads may not have a bifurcation.

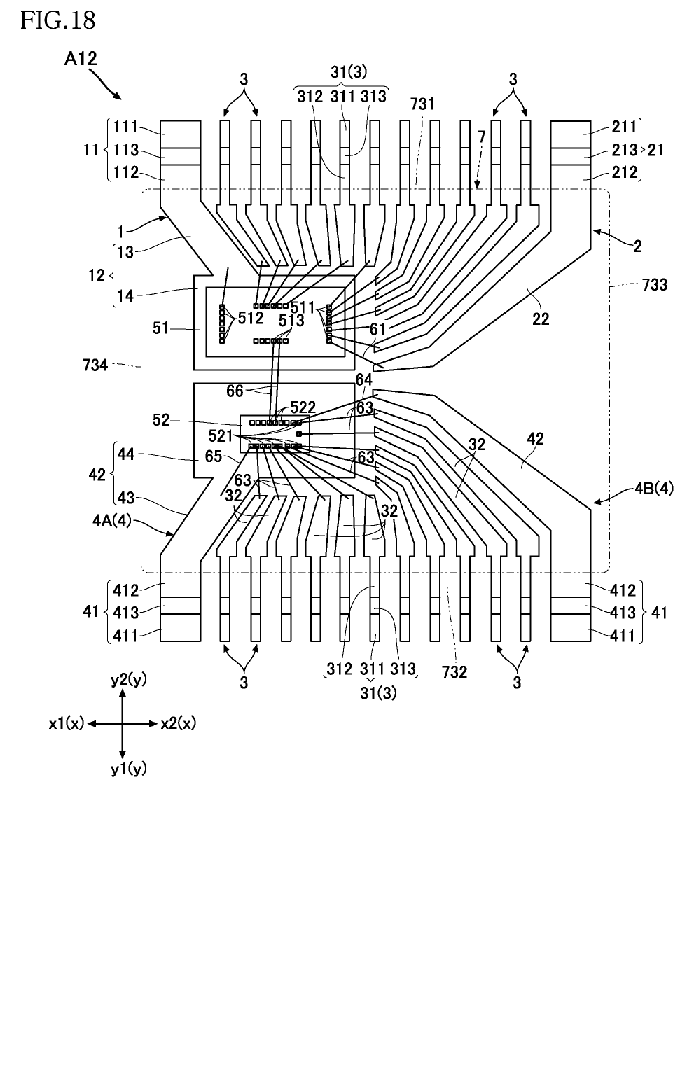

FIG. 18 shows an electronic device A12 based on a second variation of the first embodiment. The electronic device A12 may differ from the electronic device A10 in that an additional plurality of third leads 3 are provided between the first lead 1 and the second lead 2.

As shown in FIG. 18, the additional third leads 3, positioned between the first lead 1 and the second lead 2, protrude from the first resin side surface 731. The third outer portions 31 of the additional third leads 3 are positioned between the first outer portion 11 and the second outer portion 21 in the second direction x. The first outer portion 11 is positioned on the x1 side of the second direction x relative to the third outer portion 31 of the additional third leads 3. The first outer portion 11 is located most toward the x1 side in the second direction x of the first outer portion 11, the second outer portion 21, and the third outer portions 31, each protruding from the first resin side surface 731. This configuration may be adopted, for example, when the first electronic component 51 and the second electronic component 52 are ICs (Integrated Circuits).

In the electronic device A12, similar to the electronic device A10, deformation of the first lead 1 and deformation of the fourth lead 4A, i.e., deformation of the lead frame, can be reduced. Furthermore, the electronic device A12 may achieve the same effects as those of the electronic devices A10 and A11.

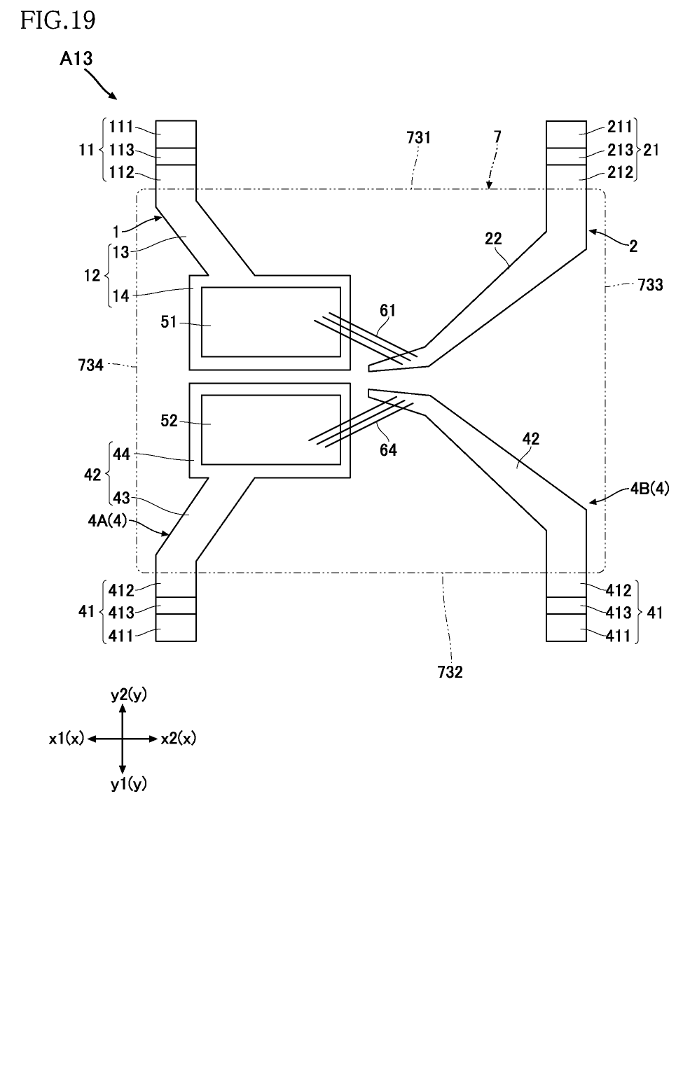

FIG. 19 shows an electronic device A13 based on a third variation of the first embodiment. The electronic device A13 may differ from the electronic device A10 in that it does not include the third leads 3 (and some of the connecting members mentioned above).

In the electronic device A13, similar to the electronic device A10, deformation of the first lead 1 and deformation of the fourth lead 4A, i.e., deformation of the lead frame, can be reduced. Furthermore, the electronic device A13 may achieve the same effects as those of the electronic devices A10 to A 12.

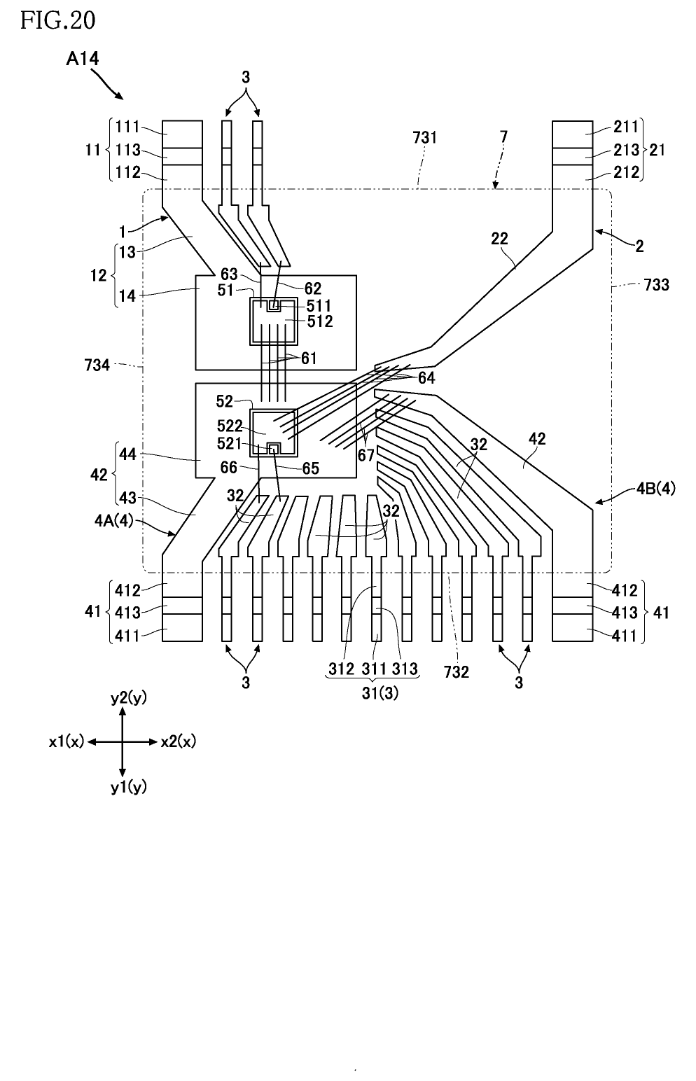

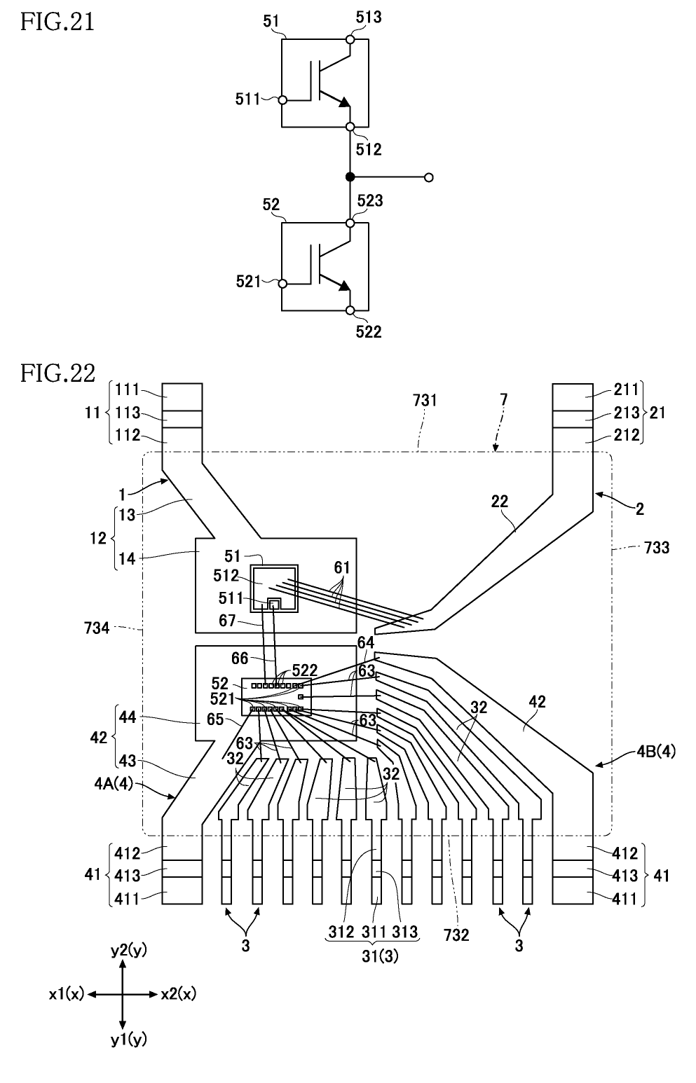

FIGS. 20 and 21 show an electronic device A14 based on a fourth variation of the first embodiment. The electronic device A14 may differ from the electronic device A10 in that the first and second electronic components 51, 52 have different functions from those mentioned above.

Specifically, in the electronic device A14, the first electronic component 51 and the second electronic component 52 have power conversion functions instead of voltage detection functions. In this variation, the first electronic component 51 and the second electronic component 52 may be switching elements. As shown in FIG. 21, the first electronic component 51 and the second electronic component 52 may be configured as IGBTs (Insulated Gate Bipolar Transistors). Alternatively, the first electronic component 51 and the second electronic component 52 may be other types of transistors, such as MOSFETs (Metal-Oxide-Semiconductor Field Effect Transistors) or bipolar transistors.

As shown in FIG. 21, the first electronic component 51 may have three electrodes 511, 512 and 513. When the first electronic component 51 is an IGBT, the electrode 511 is the gate, the electrode 512 is the emitter, and the electrode 513 is the collector. The first electronic component 51 has, for example, a vertical structure. The two electrodes 511 and 512 are arranged on its upper surface (the surface facing upward in the thickness direction z), and the electrode 513 is arranged on its lower surface (the surface facing downward in the thickness direction z). The first electronic component 51 is bonded to the first die pad portion 14 using a conductive bonding material (e.g., solder) not shown. The electrode 513 provided on the lower surface of the first electronic component 51 conducts to the first die pad portion 14 via the conductive bonding material.

As shown in FIG. 21, the second electronic component 52 has three electrodes 521, 522 and 523. When the second electronic component 52 is an IGBT, the electrode 521 is the gate, the electrode 522 is the emitter, and the electrode 523 is the collector. The second electronic component 52, for example, has a vertical structure. The two electrodes 521 and 522 are arranged on its upper surface (the surface facing upward in the thickness direction z), and the electrode 523 is arranged on its lower surface (the surface facing downward in the thickness direction z). As shown in FIG. 21, the second electronic component 52 is bonded to the second die pad portion 44 using a conductive bonding material (e.g., solder) not shown. The electrode 523 provided on the lower surface of the second electronic component 52 conducts to the second die pad portion 44 (fourth lead 4A) via the conductive bonding material.

The first electronic component 51 and the second electronic component 52 may have a horizontal structure instead of the above-mentioned vertical structure. In this case, the electrode 513 is disposed on the upper surface of the first electronic component 51, and the electrode 523 is disposed on the upper surface of the second electronic component 52. In this example, the electrode 513 and the first inner portion 12 are electrically connected by a bonding wire or a plate-shaped metal member, and the electrode 523 and the fourth inner portion 42 of the fourth lead 4A are electrically connected by a bonding wire or a plate-shaped metal member.

The electronic device A14 includes a plurality of connecting members 61 to 66 and a plurality of connecting members 67. These connecting members 61 to 67 may be bonding wires. In the electronic device A14, the configurations of the connecting members 61 to 67 is as described below.

In the electronic device A14, the connecting members 61 are bonded to the electrode 512 and the second die pad portion 44, electrically connecting them to each other. The second die pad portion 44 (the fourth inner portion 42 of the fourth lead 4A) is electrically connected to the electrode 512 via the connecting members 61. The connecting members 64 are bonded to the electrode 522 and the second inner portion 22 of the second lead 2, electrically connecting them to each other. The second lead 2 is electrically connected to the electrode 522 via the connecting members 64. The connecting members 67 are bonded to the second die pad portion 44 and the fourth inner portion 42 of the fourth lead 4B, electrically connecting them to each other. The fourth lead 4B is electrically connected to the fourth lead 4A via the connecting members 67. In the electronic device A14, the fourth lead 4A is electrically connected to the electrode 523, and the fourth lead 4B is also electrically connected to the electrode 523.

In the electronic device A14, the connecting member 62 is bonded to the electrode 511 and to the third inner portion 32 of one of the third leads 3, electrically connecting them to each other. The third outer portion 31 of the third lead 3 to which the connecting member 62 is bonded is a signal input terminal to receive a drive signal for the first electronic component 51. The connecting member 63 is bonded to the electrode 512 and the third inner portion 32 of one of the third leads 3, electrically connecting them to each other. The third outer portion 31 of the third lead 3 to which the connecting member 63 is bonded is a detection terminal to detect the current (emitter current in electronic device A14) flowing through the first electronic component 51.

In the electronic device A14, the connecting member 65 is bonded to the electrode 521 and the third inner portion 32 of one of the third leads 3, electrically connecting them to each other. The third outer portion 31 of the third lead 3 to which the connecting member 65 is bonded is a signal input terminal to receive a drive signal for the second electronic component 52. The connecting member 66 is bonded to the electrode 522 and the third inner portion 32 of one of the third leads 3, electrically connecting them to each other. The third outer portion 31 of the third lead 3 to which the connecting member 66 is connected is a detection terminal to detect the current (emitter current in electronic device A14) flowing through the second electronic component 52.

In the electronic device A14, a power supply voltage (e.g., DC voltage) is applied between the first outer portion 11 (first lead 1) and the second outer portion 21 (second lead 2). This power supply voltage is converted into a predetermined voltage (e.g., AC voltage) by the switching operations of the first electronic component 51 and the second electronic component 52. The converted voltage is outputted from the fourth outer portions 41 of the fourth leads 4 (4A, 4B).

In the electronic device A14, a predetermined number of third leads 3 are not electrically connected to the first electronic component 51 nor the second electronic component 52. Thus, the electronic device A14 may not include these non-conductive third leads 3. In the electronic device A14, the signal input terminal and the detection terminal for first electronic component 51 may also be any one of the third leads 3 disposed between the fourth leads 4A and 4B. In this case, the third leads 3 disposed between the first lead 1 and the second lead 2 may not be provided.

In the electronic device A14, similar to the electronic device A10, it is possible to reduce deformation of the first lead 1 and deformation of the fourth lead 4A, i.e., deformation of the lead frame. The electronic device A14 may also achieve the same effects as those of the electronic devices A10 to A13.

In the above fourth variation, both the first electronic component 51 and the second electronic component 52 are switching elements. Alternatively, for example, the second electronic component 52 may be a control IC configured to control the operation of the first electronic component 51. FIG. 22 shows an electronic device according to such a variation. In the electronic device shown in FIG. 22, the second electronic component 52 is configured to output a drive signal to the first electronic component 51 via a connecting member 66, while also configured to detect the current flowing in the first electronic component 51 via a connecting member 67. In the electronic device shown in FIG. 22, a plurality of connecting members 61 are bonded to the electrode 512 and the second inner portion 22. The electronic device of FIG. 22 configured in this manner may also achieve the same effects as those of the electronic device A14.

As understood from the above-described variations of the first embodiment, the functions of the first electronic component 51 and the second electronic component 52 in the electronic device of the present disclosure are not limited to voltage detection. In the electronic device of the present disclosure, the first electronic component 51 and the second electronic component 52 include semiconductor elements composed of semiconductor materials. In this case, the electronic device of the present disclosure is a semiconductor device, equipped with semiconductor elements for the first electronic component 51 and the second electronic component 52. As understood from the above variations, in the electronic device of the present disclosure, the arrangement and number of the third leads 3 and the arrangement and number of the connecting members 61 to 67 are not limited to the illustrated configuration and may be appropriately modified according to the specifications of the electronic device.

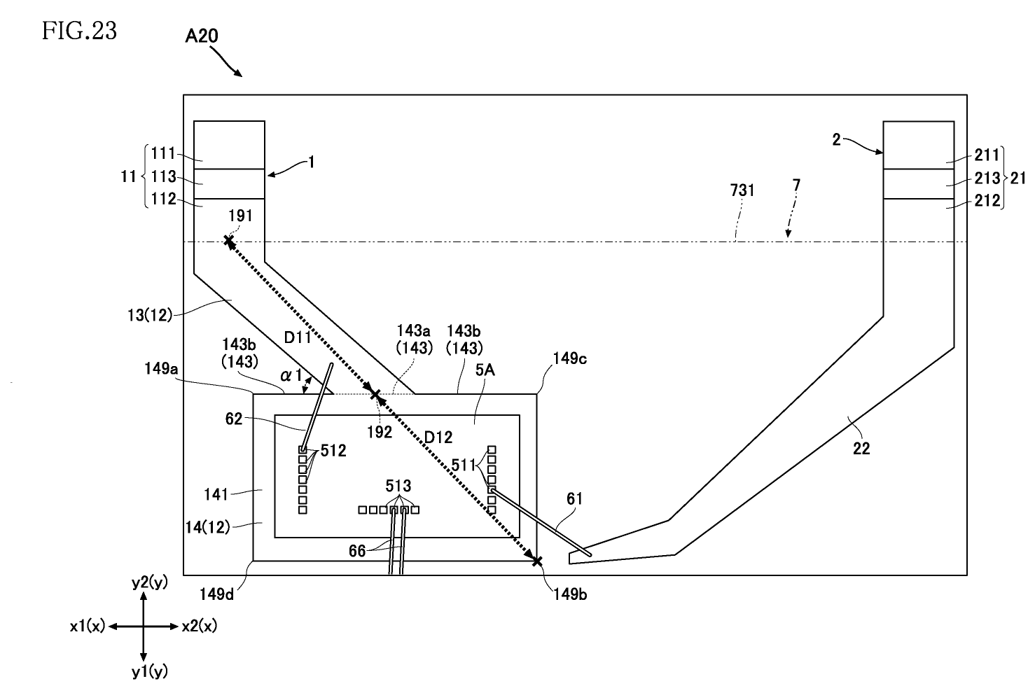

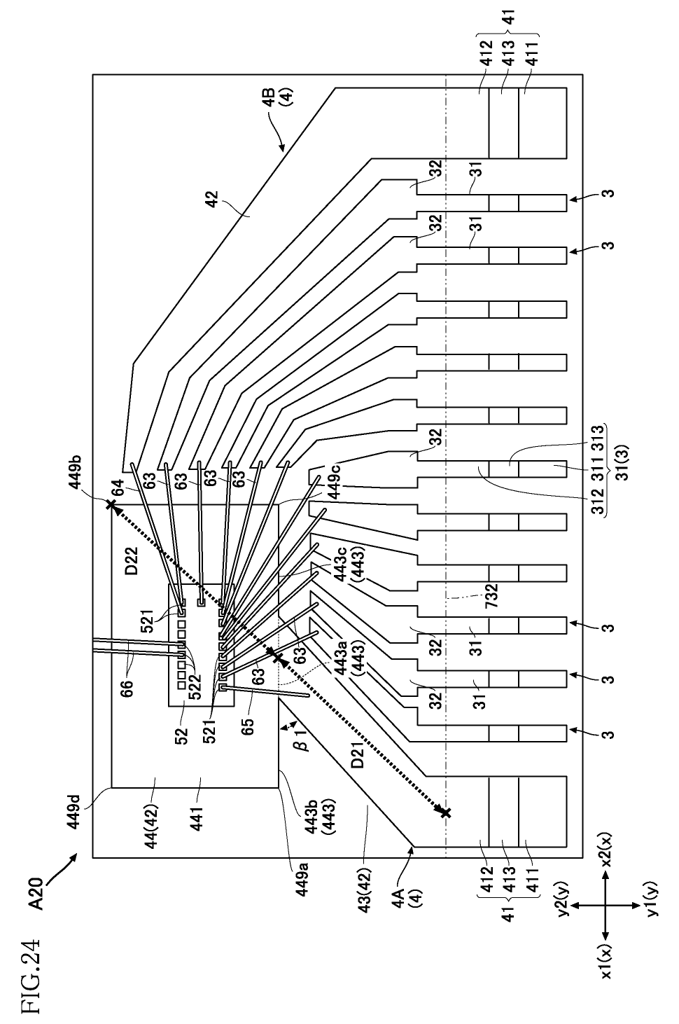

FIGS. 23 and 24 show an electronic device A20 based on a second embodiment. The electronic device A20 may differ from the electronic device A10 in the following points. First, in the electronic device A20, the first connection point 191, the second connection point 192, and the second corner 149b are aligned in a straight line. Second, in the electronic device A20, the connection point 491, the connection point 492, and the corner 449b are also aligned in a straight line.

Similar to the electronic device A10, in the electronic device A20, the first side surface 143 includes a connecting section 143a and a pair of lateral sections 143b, 143c. According to the electronic device A20, similar to the electronic device A10, deformation of the first lead 1, namely deformation of the lead frame, can be reduced. In the electronic device A20, as in the electronic device A10, the second side surface 443 includes a connecting section 443a and a pair of lateral sections 443b and 443c. According to the electronic device A20, as in the electronic device A10, deformation of the fourth lead 4A, i.e., deformation of the lead frame, can be reduced. The electronic device A20 may achieve the same effects as those of the electronic device A10 by having common configurations.

In the electronic device A20, the first connection point 191, the second connection point 192, and the second corner 149b lie on a single straight line. According to this configuration, the sum of the distance D11 between the first connection point 191 and the second connection point 192, and the distance D12 between the second connection point 192 and the second corner 149b can be minimized. Thus, the electronic device A20 may reduce deformation of the first lead 1 more effectively than the electronic device A10.

In the electronic device A, 20the connection point 491, the connection point 492, and the corner 449b lie on a single straight line. According to this configuration, the sum of the distance D21 between the connection point 491 and the connection point 492, and the distance D22 between the connection point 492 and the corner 449b can be minimized. Thus, the electronic device A20 can reduce deformation of the fourth lead 4A more effectively than the electronic device A10.

The electronic devices of the present disclosure are not limited to one having both a first electronic component 51 and a second electronic component 52, but may have only one of the first electronic component 51 and the second electronic component 52. For example, in a configuration that includes the first electronic component 51 but not the second electronic component 52, it may not include the third leads 3 and fourth leads 4. For example, in a configuration that includes the second electronic component 52 but not the first electronic component 51, it may not include the first lead 1 and second lead 2.

The electronic devices of the present disclosure are not limited to the embodiments and variations described above. The specific configurations of the parts of the electronic devices of the present disclosure may be modified in various ways. The present disclosure includes the embodiments described in the following clauses.

### Clause 1.

An electronic device comprising: a first electronic component; a sealing resin covering the electronic component; and a first lead including a first inner portion covered by the sealing resin and a first outer portion exposed from the sealing resin, wherein the first inner portion includes a first die pad portion on which the electronic component is mounted, and a first connecting portion that connects the first outer portion and the first die pad portion to each other, the first outer portion is disposed on a first side of a first direction perpendicular to a thickness direction of the electronic component relative to the first die pad portion, the first die pad portion includes a first side surface facing a side where the first outer portion is located in the first direction, the first connecting portion is connected to the first side surface, in a second direction perpendicular to the first direction, a center of the first outer portion is disposed on a first side of the second direction relative to a center of the first die pad portion, and the first side surface includes a connecting section connected to the first connecting portion, and a pair of lateral sections disposed on respective sides of the connecting section in the second direction. Clause 2.

The electronic device according to clause 1, wherein the first die pad portion is rectangular as viewed in the thickness direction, as viewed in the thickness direction, the first die pad portion includes a first corner located on the first side of the first direction and the first side of the second direction, and a second corner located diagonally opposite to the first corner.

### Clause 3.

The electronic device according to clause 2, wherein the first inner portion and the first outer portion define a boundary having a center as a first connection point, the first connecting portion and the first die pad portion define a boundary having a center as a second connection point, as viewed in the thickness direction, the first connection point, the second connection point and the second corner lie on a single straight line.

### Clause 4.

The electronic device according to clause 1 or 2, wherein the connecting section is disposed on the first side of the second direction relative to a center of the first side surface in the second direction.

### Clause 5.

The electronic device according to any of clauses 1-4, wherein the connecting section and the electronic component are spaced apart from each other in the first direction as viewed in the thickness direction.

### Clause 6.

The electronic device according to any of clauses 1-5, wherein the first connecting portion is inclined relative to the first side surface as viewed in the thickness direction.

### Clause 7.

The electronic device according to clause 6, wherein an inclination angle of the first connecting portion relative to the first side surface is at least 10° and at most 89°.

### Clause 8.

The electronic device according to any of clauses 1-7, further comprising: a second lead spaced apart from the first lead; and a connecting member bonded to the second lead and the electronic component, wherein the second lead includes a second inner portion covered by the sealing resin and a second outer portion exposed from the sealing resin, and the connecting member is covered by the sealing resin and bonded to the second inner portion.

### Clause 9.

The electronic device according to clause 8, wherein the sealing resin includes a first resin side surface facing the first side of the first direction, and the first lead and the second lead protrude from the first resin side surface.

### Clause 10.

The electronic device according to clause 9, further comprising a plurality of third leads spaced apart from the first lead and the second lead, wherein the each of the plurality of third leads includes a third inner portion covered by the sealing resin and a third outer portion exposed from the sealing resin.

### Clause 11.

The electronic device according to clause 10, wherein the plurality of third leads protrude from the first resin side surface, and the first outer portion is disposed on the first side of the second direction relative to the second outer portion and the third outer portions of the plurality of third leads.

### Clause 12.

The electronic device according to clause 10, wherein the sealing resin includes a second resin side surface facing away from the first resin side surface in the first direction, the plurality of third leads protrude from the second resin side surface as viewed in the thickness direction.

### Clause 13.

The electronic device according to clause 12, wherein the first outer portion and the second outer portion are adjacent to each other with a first spacing in the second direction, the third outer portions of the plurality of third leads are mutually spaced apart with a second spacing in the second direction, and the first spacing is greater than the second spacing.

### Clause 14.

The electronic device according to clause 13, further comprising a pair of fourth leads each including a fourth inner portion covered by the sealing resin and a fourth outer portion exposed from the sealing resin, wherein each of the pair of fourth leads is spaced apart from the first lead, the second lead and the plurality of third leads, and protrudes from the second resin side surface as viewed in the thickness direction, and the fourth outer portions of the pair of fourth leads are disposed on respective sides of the third outer portions of the plurality of third leads in the first direction.

### Clause 15.

The electronic device according to clause 14, further comprising a second electronic component in addition to the first electronic component, wherein the pair of fourth leads are spaced apart from each other, and in one of the pair of fourth leads, the fourth inner portion includes a second die pad portion on which the second electronic component is mounted, and a second connecting portion that connects the fourth outer portion and the second die pad portion to each other.

### Clause 16.

The electronic device according to clause 15, wherein the second die pad portion includes a second side surface facing a side where the fourth outer portion of the one of the pair of fourth leads is located in the first direction, the second connecting portion is connected to the second side surface, and a center of the fourth outer portion of the one of the pair of fourth leads is offset relative to a center of the second die pad portion in the second direction.

### REFERENCE NUMERALS

A10-A14, A20: electronic device 1: first lead 11: first outer portion 111: first mounting portion 112: first base portion 113: first intermediate portion 12: firs inner portion 13: first connecting portion 14: first die pad portion 141: obverse surface 142: reverse surface 143: first side surface 143a: connecting section 143b, 143c: lateral section 149a: first corner 149b: second corner 149c, 149d: corner 191: first connection point 192: second connection point 2: second lead 21: second outer portion 211: second mounting portion 212: second base portion 213: second intermediate portion 22: second inner portion 3: third lead 31: third outer portion 311: third mounting portion 312: third base portion 313: third intermediate portion 32: third inner portion 4: fourth lead 4A : fourth lead 4B: fourth lead 41: fourth outer portion 411: fourth mounting portion 412: fourth base portion 413: fourth intermediate portion 42: fourth inner portion 43: second connecting portion 44: second die pad portion 441: obverse surface 442: reverse surface 443: second side surface 443a: connecting section 443b, 443c: lateral section 449a-449d: corner 491, 492: connection point 51: first electronic component 511, 512, 513: electrode 52: second electronic component 521, 522, 523: electrode 61-67: connecting member 7: sealing resin 71: resin obverse surface 72: resin reverse surface 731: first resin side surface 732: second resin side surface 733, 734: resin side surface 9: lead frame 91: tie bar C1, C2: connection part GND: ground OP: operational amplifier R1-R5: resistor T1, T2: terminal

1. An electronic device comprising:
a first electronic component;
a sealing resin covering the electronic component; and
a first lead including a first inner portion covered by the sealing resin and a first outer portion exposed from the sealing resin,
wherein the first inner portion includes a first die pad portion on which the electronic component is mounted, and a first connecting portion that connects the first outer portion and the first die pad portion to each other,
the first outer portion is disposed on a first side of a first direction perpendicular to a thickness direction of the electronic component relative to the first die pad portion,
the first die pad portion includes a first side surface facing a side where the first outer portion is located in the first direction,
the first connecting portion is connected to the first side surface,
in a second direction perpendicular to the first direction, a center of the first outer portion is disposed on a first side of the second direction relative to a center of the first die pad portion, and
the first side surface includes a connecting section connected to the first connecting portion, and a pair of lateral sections disposed on respective sides of the connecting section in the second direction.

2. The electronic device according to claim 1, wherein the first die pad portion is rectangular as viewed in the thickness direction,
as viewed in the thickness direction, the first die pad portion includes a first corner located on the first side of the first direction and the first side of the second direction, and a second corner located diagonally opposite to the first corner.

3. The electronic device according to claim 2, wherein the first inner portion and the first outer portion define a boundary having a center as a first connection point,
the first connecting portion and the first die pad portion define a boundary having a center as a second connection point,
as viewed in the thickness direction, the first connection point, the second connection point and the second corner lie on a single straight line.

4. The electronic device according to claim 1, wherein the connecting section is disposed on the first side of the second direction relative to a center of the first side surface in the second direction.

5. The electronic device according to claim 1, wherein the connecting section and the electronic component are spaced apart from each other in the first direction as viewed in the thickness direction.

6. The electronic device according to claim 1, wherein the first connecting portion is inclined relative to the first side surface as viewed in the thickness direction.

7. The electronic device according to claim 6, wherein an inclination angle of the first connecting portion relative to the first side surface is at least 10° and at most 89°.

8. The electronic device according to claim 1, further comprising:
a second lead spaced apart from the first lead; and
a connecting member bonded to the second lead and the electronic component,
wherein the second lead includes a second inner portion covered by the sealing resin and a second outer portion exposed from the sealing resin, and
the connecting member is covered by the sealing resin and bonded to the second inner portion.

9. The electronic device according to claim 8, wherein the sealing resin includes a first resin side surface facing the first side of the first direction, and
the first lead and the second lead protrude from the first resin side surface.

10. The electronic device according to claim 9, further comprising a plurality of third leads spaced apart from the first lead and the second lead,
wherein the each of the plurality of third leads includes a third inner portion covered by the sealing resin and a third outer portion exposed from the sealing resin.

11. The electronic device according to claim 10, wherein the plurality of third leads protrude from the first resin side surface, and
the first outer portion is disposed on the first side of the second direction relative to the second outer portion and the third outer portions of the plurality of third leads.

12. The electronic device according to claim 10, wherein the sealing resin includes a second resin side surface facing away from the first resin side surface in the first direction,
the plurality of third leads protrude from the second resin side surface as viewed in the thickness direction.

13. The electronic device according to claim 12, wherein the first outer portion and the second outer portion are adjacent to each other with a first spacing in the second direction,
the third outer portions of the plurality of third leads are mutually spaced apart with a second spacing in the second direction, and
the first spacing is greater than the second spacing.

14. The electronic device according to claim 13, further comprising a pair of fourth leads each including a fourth inner portion covered by the sealing resin and a fourth outer portion exposed from the sealing resin,
wherein each of the pair of fourth leads is spaced apart from the first lead, the second lead and the plurality of third leads, and protrudes from the second resin side surface as viewed in the thickness direction, and
the fourth outer portions of the pair of fourth leads are disposed on respective sides of the third outer portions of the plurality of third leads in the first direction.

15. The electronic device according to claim 14, further comprising a second electronic component in addition to the first electronic component,
wherein the pair of fourth leads are spaced apart from each other, and
in one of the pair of fourth leads, the fourth inner portion includes a second die pad portion on which the second electronic component is mounted, and a second connecting portion that connects the fourth outer portion and the second die pad portion to each other.

16. The electronic device according to claim 15, wherein the second die pad portion includes a second side surface facing a side where the fourth outer portion of the one of the pair of fourth leads is located in the first direction,
the second connecting portion is connected to the second side surface, and
a center of the fourth outer portion of the one of the pair of fourth leads is offset relative to a center of the second die pad portion in the second direction.
